(19) United States
(12) Patent Application Publication
(10) Pub. No.: US 2025/0079167 A1
(43) Pub. Date: Mar. 6, 2025

(54) METHODS OF FORMING SEMICONDUCTOR STRUCTURES, SEMICONDUCTOR PROCESSING SYSTEMS AND RELATED COMPUTER PROGRAM PRODUCTS

(71) Applicant: ASM IP Holding B.V., Almere (NL)

(72) Inventors: Ernesto Suarez, Scottsdale, AZ (US); Amir Kajbafvala, Chandler, AZ (US); Arun Murali, Tempe, AZ (US); Caleb Miskin, Mesa, AZ (US); Alexandros Demos, Scottsdale, AZ (US)

(21) Appl. No.: 18/815,636

(22) Filed: Aug. 26, 2024

Related U.S. Application Data
(60) Provisional application No. 63/579,553, filed on Aug. 30, 2023.

(51) Int. Cl. H01L 21/02; H01L 21/306; H01L 21/3065; H01L 29/167

(52) U.S. Cl. CPC H01L 21/02532; H01L 21/02579; H01L 21/0262; H01L 21/30604; H01L 21/3065; H10D 62/834

(57) ABSTRACT

A method of forming a semiconductor structure includes seating a substrate on a substrate support arranged within a chamber arrangement of a semiconductor processing system, flowing a boron-containing precursor to the chamber arrangement at a first boron-containing precursor mass flow rate, and depositing a first portion of a first SiGe:B layer using the boron-containing precursor. Mass flow rate of the boron-containing precursor to an intermediate boron-containing precursor flow rate, a second portion of the first SiGe:B layer is deposited using the boron-containing precursor, mass flow rate of the boron-containing precursor to the chamber arrangement is further increased to a second boron-containing precursor mass flow rate, and a second SiGe:B layer is deposited onto the first SiGe:B layer using the boron-containing precursor, the increase in the mass flow rate of the boron-containing precursor to the intermediate boron-containing precursor mass flow rate limits boron concentration at a first SiGe:B layer-to-second SiGe:B layer interface defined between the first SiGe:B layer and the second SiGe:B layer to less than a boron concentration within the second SiGe:B layer. Semiconductor processing systems and related computer program products are also provided.

### CROSS-REFERENCE TO RELATED APPLICATION(S)

This Application claims the benefit of U.S. Provisional Application 63/579,553 filed on Aug. 30, 2023, the entire contents of which are incorporated herein by reference.

### FIELD OF INVENTION

The present disclosure generally relates to forming semiconductor structures. More particularly, the present disclosure relates to forming semiconductor structures and related computer program products, during the fabrication of semiconductor devices.

### BACKGROUND OF THE DISCLOSURE

Material layers are commonly deposited onto substrates, such as during the fabrication of semiconductor devices. Material layer deposition is generally accomplished by heating a substrate to a desired deposition pressure and exposing the substrate to a material layer precursor under environmental conditions selected to cause a material layer to deposit onto the substrate. Once the material layer develops desired one or more desired property the substrate is typically sent on for further processing, as appropriate for the device being fabricated.

In some material layer deposition methods deposition may entail exposing the substrate to more than one material layer precursor. Where the precursors include constituents with disparate incorporation affinities and/or migration tendency such as boron, countermeasures may be necessary to offset the disparate affinities and migration tendency, for example by ceasing deposition of one layer prior to depositing an overlaying layer. While generally satisfactory, deposition processes employing such countermeasures may prolong the deposition process.

Such systems and methods have generally been accepted for their intended purpose. However, there remains a need for improved methods of forming semiconductor structures, semiconductor processing systems, and related computer program products. The present disclosure provides a solution to this need.

SUMMARY OF THE DISCLOSURE

A method of forming a semiconductor processing system is provided. The method includes seating a substrate on a substrate support arranged within a chamber arrangement of a semiconductor processing system, flowing a boron-containing precursor to the chamber arrangement at a first boron-containing precursor mass flow rate, and depositing a first portion of a first SiGe:B layer using the boron-containing precursor. Mass flow rate of the boron-containing precursor to an intermediate boron-containing precursor flow rate, a second portion of the first SiGe:B layer is deposited using the boron-containing precursor, mass flow rate of the boron-containing precursor to the chamber arrangement is further increased to a second boron-containing precursor mass flow rate, and a second SiGe:B layer is deposited onto the first SiGe:B layer using the boron-containing precursor, the increase in the mass flow rate of the boron-containing precursor to the intermediate boron-containing precursor mass flow rate limits boron concentration at a first SiGe:B layer-to-second SiGe:B layer interface defined between the first SiGe:B layer and the second SiGe:B layer to less than a boron concentration within the second SiGe:B layer.

In addition to one or more of the features described above, or as an alternative, further examples of the method may include that the first portion of the first SiGe:B layer is formed during a first portion deposition interval, that the second portion of the first SiGe:B layer is formed during a second portion deposition interval, and that the second portion deposition interval is shorter than the first portion deposition interval.

In addition to one or more of the features described above, or as an alternative, further examples of the method may include that the first SiGe:B layer intermediate boron-containing precursor mass flow rate is between about 110% and about 200% of the first SiGe:B layer first boron-containing precursor mass flow rate. The method may include the first SiGe:B layer second boron-containing precursor is between about 150% and about 250% of the first SiGe:B layer intermediate boron-containing precursor mass flow rate.

In addition to one or more of the features described above, or as an alternative, further examples of the method may include that the second portion deposition interval is between about 10% and about 40% of the first portion deposition interval.

In addition to one or more of the features described above, or as an alternative, further examples of the method may include mass flow rate of the boron-containing precursor may be substantially constant during the first portion deposition interval.

In addition to one or more of the features described above, or as an alternative, further examples of the method may include mass flow rate of the boron-containing precursor may progressive increased during the second portion deposition interval.

In addition to one or more of the features described above, or as an alternative, further examples of the method may include flowing a silicon-containing precursor to the chamber arrangement during deposition of the first portion of the first SiGe:B layer; flowing a germanium-containing precursor to the chamber arrangement during deposition of the first portion of the first SiGe:B layer; and increasing a ratio of germanium-containing precursor mass flow rate (and/or mass) to silicon-containing precursor mass flow rate (and/or mass) during deposition of the second portion of the first SiGe:B layer.

In addition to one or more of the features described above, or as an alternative, further examples of the method may include that increasing the ratio of the germanium-containing precursor to the silicon-containing precursor flowed to the chamber arrangement during deposition of the second portion of the SiGe:B layer includes flowing the germanium-containing precursor to the chamber arrangement at a first germanium-containing precursor mass flow rate during deposition of the first portion of the first SiGe:B layer; increasing the first germanium-containing precursor mass flow rate to a second germanium-containing precursor mass flow rate during deposition of the second portion of the first SiGe:B layer; and flowing the germanium-containing precursor to the chamber arrangement at the second germanium-containing precursor mass flow rate during deposition of the second SiGe:B layer.

In addition to one or more of the features described above, or as an alternative, further examples of the method may include that the second germanium-containing precursor mass flow rate may be between about 150% and about 400% of the first germanium-containing precursor mass flow rate.

In addition to one or more of the features described above, or as an alternative, further examples of the method may include that the second germanium-containing precursor mass flow rate may remain substantially constant during deposition of the second SiGe:B layer.

In addition to one or more of the features described above, or as an alternative, further examples of the method may include that mass flow rate of the germanium-containing precursor may remain substantially constant during definition of the first SiGe:B layer-to-second SiGe:B layer interface.

In addition to one or more of the features described above, or as an alternative, further examples of the method may include that increasing the ratio of the germanium-containing precursor to the silicon-containing precursor flowed to the chamber arrangement during deposition of the second portion of the SiGe:B layer may include flowing the silicon-containing precursor to the chamber arrangement at a first silicon-containing precursor mass flow rate during deposition of the first portion of the first SiGe:B layer; increasing the first silicon-containing precursor mass flow rate to a second silicon-containing precursor mass flow rate during deposition of the second portion of the first SiGe:B layer; and flowing the silicon-containing precursor to the chamber arrangement at the second silicon-containing precursor mass flow rate during deposition of the second SiGe:B layer.

In addition to one or more of the features described above, or as an alternative, further examples of the method may include that the second silicon-containing precursor mass flow rate may be between about 105% and about 125% of the first silicon-containing precursor mass flow rate.

In addition to one or more of the features described above, or as an alternative, further examples of the method may include that the first silicon-containing precursor mass flow rate flowed to the chamber arrangement remains constant during definition of the first SiGe:B layer-to-second SiGe:B layer interface between the first SiGe:B layer and the second SiGe:B layer.

In addition to one or more of the features described above, or as an alternative, further examples of the method may include flowing at etchant to the chamber arrangement at a first etchant mass flow rate during deposition of the first portion of the first SiGe:B layer; increasing flow rate of the etchant to a second etchant mass flow rate during deposition of the second portion of the first SiGe:B layer; and flowing the etchant to the chamber arrangement at the second etchant mass flow rate during deposition of the second SiGe:B layer.

In addition to one or more of the features described above, or as an alternative, further examples of the method may include that the second etchant mass flow rate is between about 150% and about 600% of the first etchant mass flow rate.

In addition to one or more of the features described above, or as an alternative, further examples of the method may include that the first SiGe:B layer and the second SiGe:B layer are deposited continuously and without interruption.

In addition to one or more of the features described above, or as an alternative, further examples of the method may include that the substrate having a trench defined within an upper surface of the substrate. The method may further include depositing a silicon germanium (SiGe) layer onto a lower surface and sidewalls bounding the trench, and that the first SiGe:B layer is deposited onto the SiGe layer.

In addition to one or more of the features described above, or as an alternative, further examples of the method may include that the first SiGe:B layer is deposited within the trench and onto the SiGe layer, that the second SiGe:B layer protrudes above the upper surface of the substrate, and that the method further includes depositing a boron-doped silicon layer onto the second SiGe:B layer.

In addition to one or more of the features described above, or as an alternative, further examples of the method may include depositing a SiGe intermediate layer onto the second SiGe:B layer. It is contemplated that a boron-doped silicon (Si:B) layer may be deposited onto the SiGe intermediate layer.

In addition to one or more of the features described above, or as an alternative, further examples of the method may include depositing the SiGe intermediate layer by ceasing flow of the boron-containing precursor and simultaneously reducing flow of the germanium-containing precursor to the chamber arrangement, and thereafter continuing to flow the germanium-containing precursor to the chamber arrangement prior to resuming flow of the boron-containing precursor to the chamber arrangement. Flow of the etchant to the chamber arrangement may be reduced simultaneously with reduction of flow of the germanium-containing precursor and the etchant flowed at the reduced flow rate until flow of the boron-containing precursor to the chamber arrangement is resumed.

A semiconductor structure is provided. The semiconductor structure is formed from the above-described method of forming a semiconductor structure, the second SiGe:B layer has a greater thickness than the first SiGe:B layer, the second SiGe:B layer has a greater germanium concentration that the first SiGe:B layer, and the second SiGe:B layer has a greater boron concentration than the first SiGe:B layer.

In addition to one or more of the features described above, or as an alternative, further examples of the semiconductor structure may include that the first SiGe:B layer and the second SiGe:B layer define a first SiGe:B layer-to-second SiGe:B layer interface therebetween, and that boron concentration at the first SiGe:B layer-to-second SiGe:B layer interface is less than a boron concentration with the second SiGe:B layer during a method where the second SiGe:B layer is deposited onto the first SiGe:B layer continuously and without interruption.

In addition to one or more of the features described above, or as an alternative, further examples of the semiconductor structure may include that the second SiGe:B layer has a boron concentration and a second SiGe layer thickness. The second SiGe:boron concentration may be substantially uniform through the second SiGe:B layer thickness.

In addition to one or more of the features described above, or as an alternative, further examples of the semiconductor structure may include that the first SiGe:B layer has a first portion and an overlaying second portion, that boron concentration may be substantially uniform within a thickness of the first portion of the first SiGe:B layer, and boron concentration may be substantially uniform with a thickness of the second portion of the second SiGe:B layer.

In addition to one or more of the features described above, or as an alternative, further examples of the semiconductor structure may include that a SiGe intermediate layer may be deposited onto the second SiGe:B layer, and that a boron-doped silicon (Si:B) layer may be deposited onto the second SiGe:B layer. The SiGe intermediate layer may consist of or consist essentially of SiGe. The SiGe intermediate may have a greater germanium concentration than the second SiGe:B layer. The Si:B layer consist of or consist essentially of boron-doped silicon.

A computer program product is provided. The computer program product includes a non-transitory machine-readable medium having instructions that, when read by a processor, cause the processor to: seat a substrate on a substrate support arranged within a chamber arrangement of a semiconductor processing system; flow a boron-containing precursor to the chamber arrangement at a first boron-containing precursor mass flow rate; deposit a first portion of a first SiGe:B layer using the boron-containing precursor; increase mass flow rate of the boron-containing precursor to an intermediate boron-containing precursor flow rate; deposit a second portion of the first SiGe:B layer using the boron-containing precursor; further increase mass flow rate of the boron-containing precursor to the chamber arrangement to a second boron-containing precursor mass flow rate; and deposit a second SiGe:B layer onto the first SiGe:B layer using the boron-containing precursor such that the increase in the mass flow rate of the boron-containing precursor to the intermediate boron-containing precursor flow limits boron concentration at a first SiGe:B layer-to-second SiGe:B layer interface defined between the first SiGe:B layer and the second SiGe:B layer to less than a boron concentration within the second SiGe:B layer.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system, showing a precursor flowing from a precursor delivery arrangement to chamber arrangement to form a semiconductor structure on a substrate seated within the chamber arrangement;

FIGS. 2 and 3 are schematic views portions of the semiconductor processing system of FIG. 1 according to an example of the present disclosure, showing a precursor delivery arrangement and the chamber arrangement according to an example of the disclosure;

FIG. 4 is cross-sectional side view of the semiconductor structure of FIG. 1 according to an example of the present disclosure, showing the semiconductor structure formed within a trench defined within an upper surface of the substrate;

FIGS. 5-10 are sequential views of a portion of the substrate of FIG. 1 according to an example of the present disclosure, sequentially showing a semiconductor structure being formed within a trench defined within an upper surface of the substrate; and

FIG. 11 is graph of precursor and etchant mass flow rates during forming of the semiconductor structure of FIG. 1, comparatively showing mass flow rate changes to precursors to limit boron accumulation at an interface defined between a first boron-doped silicon germanium layer and a second boron-doped silicon germanium layer; and

FIGS. 12-16 are a block diagram of a method of making a semiconductor structure using the semiconductor processing system of FIG. 1, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

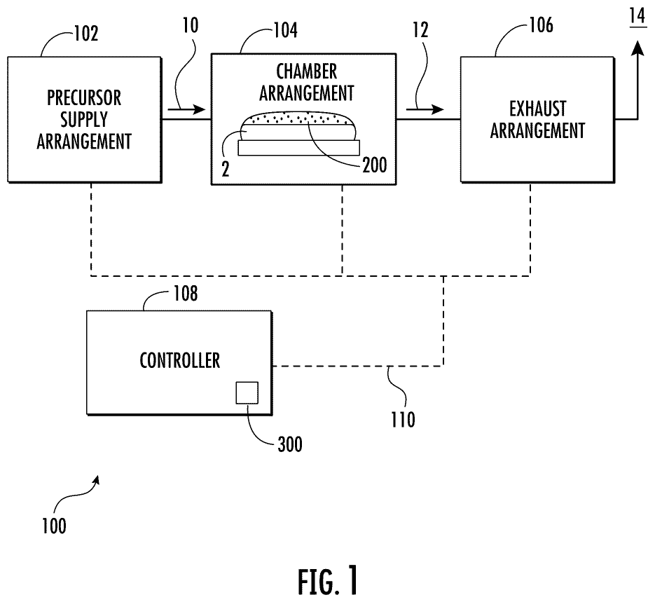

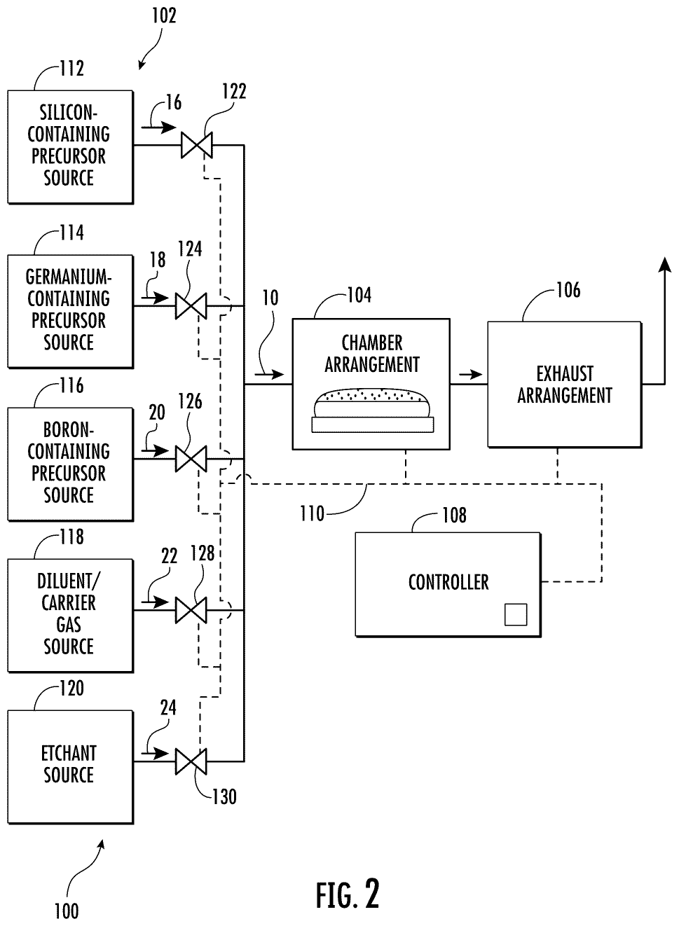

Reference will now be made to the drawings wherein like reference numerals identify similar structural features or aspects of the subject disclosure. For purposes of explanation and illustration, and not limitation, a partial view of an example of semiconductor processing system in accordance with the present disclosure is shown in FIG. 1 and is designated generally by reference character 100. Other examples of semiconductor processing systems, semiconductor structures, and methods of making semiconductor structures in accordance with the present disclosure, or aspects thereof, are provided in FIGS. 2-16, as will be described. The systems and methods of the present disclosure may be used to form semiconductor structures including boron-doped silicon germanium (SiGe:B) layers, such as in semiconductor devices employing boron-doped SiGe:B layers to control electrical properties within semiconductor devices having three-dimensional device architectures like gate-all-around (GAA) and three-dimensional dynamic random access memory (3D DRAM) semiconductor devices, though the present disclosure is not limited to any particular semiconductor device architecture or particular employment of semiconductor structures having SiGe:B layers in general.

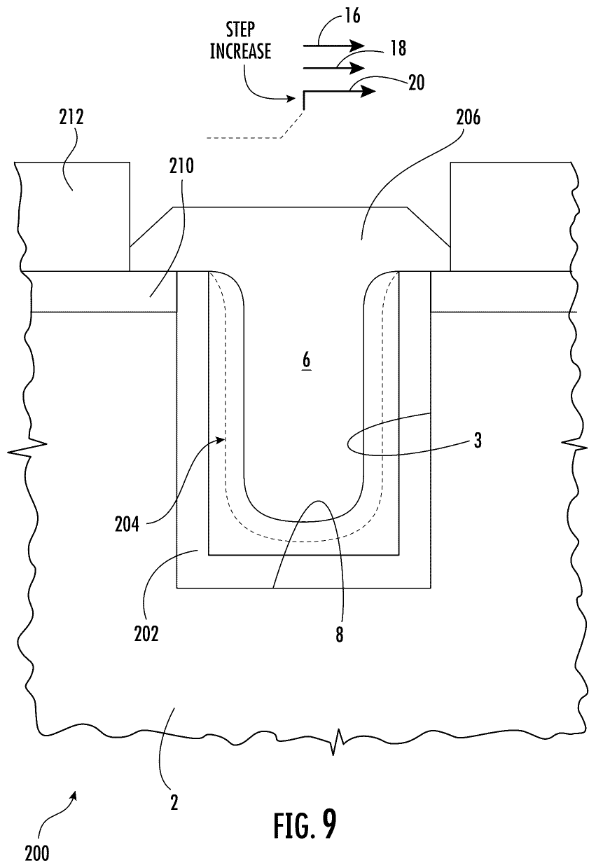

Referring to FIG. 1, the semiconductor processing system 100 is shown. The semiconductor processing system 100 generally includes a precursor supply arrangement 102, a chamber arrangement 104, an exhaust arrangement 106, and a controller 108. The precursor supply arrangement 102 is connected to the chamber arrangement 104 and is configured to provide a flow of a precursor 10 to the chamber arrangement 104. The chamber arrangement 104 is connected to the exhaust arrangement 106 is configured to expose a substrate 2 seated within the chamber arrangement 104 to the precursor 10 to form the semiconductor structure 200. The exhaust arrangement 106 is connected to the chamber arrangement 104 and is configured to communicate a flow of residual precursor and/or reaction products 12 to an external environment 14 outside of the chamber arrangement 104 and is in this respect may include one or more of a vacuum pump and/or an abatement device such as a scrubber. The controller 108 is operatively connected to the semiconductor processing system 100 (e.g., to one or more of the precursor delivery arrangement, the chamber arrangement 104 and the exhaust arrangement 106), such as through a wired or wireless link 110, and is configured to form the semiconductor structure 200, for example using a computer program product 300 having instructions recorded thereon to cause the semiconductor processing system 100 to execute operations of a method 400 (shown in FIG. 9) of making a semiconductor structure, as will be described.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may an unpatterned, blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the precursor supply arrangement 102 is shown according to an example of the present disclosure. In the illustrated example the precursor supply arrangement 102 includes a silicon-containing precursor source 112, a germanium-containing precursor source 114, and a boron-containing precursor source 116. As shown and described herein the precursor supply arrangement 102 also includes a diluent/carrier gas source 118 and an etchant source 120. In certain examples, the precursor supply arrangement 102 may be as shown and described in U.S. Pat. No. 11,053,591, to Ma et al., issued Jul. 6, 2021, the contents of which are incorporated herein by reference in its entirety. Although shown and describe herein as having certain elements and a specific arrangement, it is to be understood and appreciated that the precursor supply arrangement 102 may include other elements and/or exclude elements shown and described herein in other examples, and/or have a differing arrangement in other examples and remain within the scope of the present disclosure.

The silicon-containing precursor source 112 includes a silicon-containing precursor 16 and is connected to the chamber arrangement 104, for example through a silicon-containing precursor supply valve 122 and is configured to flow the silicon-containing precursor 16 to the chamber arrangement 104. The silicon-containing precursor supply valve 122 may in turn be operatively associated with the controller 108, may include a mass flow controller (MFC) device, and may cooperate with one or more of a mass flow meter and a diverter valve to flow the silicon-containing precursor 16 to the chamber arrangement 104. In certain examples the silicon-containing precursor 16 may include a non-chlorinated silicon-containing precursor. Non-limiting examples of suitable silicon-containing precursors includes silane (SiH₄), disilane (S₂H₆), and trisilane (Si₃H₈). In accordance with certain examples, the silicon-containing precursor 16 may include a chlorinated silicon-containing precursor. Non-limiting examples of chlorinated silicon-containing precursors include dichlorosilane (H₂SiCl₂) and trichlorosilane (HCl₃Si). As will be appreciated by those of skill in the art in view of the present disclosure, other silicon-containing precursors as well as mixtures of the aforementioned silicon-containing precursors may be employed and remain within the scope of the present disclosure.

The germanium-containing precursor source 114 includes a germanium-containing precursor 18 and is connected to the chamber arrangement 104, for example through a germanium-containing precursor supply valve 124 and is configured to flow the germanium-containing precursor 18 to the chamber arrangement 104. The germanium-containing precursor supply valve 124 may in turn be operatively associated with the controller 108, may include an MFC device, and may cooperate with one or more of a mass flow meter and a diverter valve to flow the germanium-containing precursor 18 to the chamber arrangement 104. In certain examples the germanium-containing precursor 18 may include germane (GeH₄), digermane (Ge₂H₆), trigermane (Ge₃H₈), or germylsilane (GeH₆Si). In accordance with certain examples, the germanium-containing precursor 18 may include a halogenated germanium-containing precursor such as germanium bromide (GeBr₄) and germanium tetrachloride (GeCl₄). As will be appreciated by those of skill in the art in view of the present disclosure, the germanium-containing precursor 18 may include other germanium-containing precursor and/or mixtures including one or more of the aforementioned germanium-containing precursors and remain within the scope of the present disclosure.

The boron-containing precursor source 116 includes a boron-containing precursor 20 and is connected to the chamber arrangement 104, for example through a boron-containing precursor supply valve 126 and is configured to flow the boron-containing precursor 20 to the chamber arrangement 104. The boron-containing precursor supply valve 126 may in turn be operatively associated with the controller 108, may include an MFC device, and may cooperate with one or more of a mass flow meter and a diverter valve to flow the boron-containing precursor 20 to the chamber arrangement 104. In certain examples the boron-containing precursor 20 may include diborane (B₂H₆). In accordance with certain examples, the boron-containing precursor 20 may include boron trichloride (BCl₃). As will be appreciated by those of skill in the art in view of the present disclosure, the boron-containing precursor 20 may include other boron-containing precursors and/or mixtures including one or more of the aforementioned boron-containing precursors and remain within the scope of the present disclosure.

The diluent/carrier gas source 118 includes a diluent/carrier gas 22 and is connected to the chamber arrangement 104, for example through a diluent/carrier gas supply valve 128 and is configured to flow the diluent/carrier gas 22 to the chamber arrangement 104. In this respect the diluent/carrier gas supply valve 128 may be operatively associated with the controller 108, may be incorporated in an MFC device, and may cooperate with one or more of a mass flow meter and a diverter valve to flow the diluent/carrier gas 22 to the chamber arrangement 104. In further respect, the diluent/carrier gas source 118 may be configured to intermix the diluent/carrier gas 22 with the one or more of the silicon-containing precursor 16, the germanium-containing precursor 18, and the boron-containing precursor 20 to flow with (and thereby convey) one or more of the aforementioned precursors to the chamber arrangement 104. In certain examples the diluent/carrier gas 22 may include a noble gas such as argon (Ar) gas, helium (He) gas, and krypton (Kr) gas. In accordance with certain examples, the diluent/carrier gas 22 may include nitrogen (N₂) gas, hydrogen (H₂) gas, or one a mixture including one or more of the aforementioned diluent/carrier gases. As will be appreciated by those of skill in the art in view of the present disclosure, other diluent/carrier gases may be employed, or mixtures of the aforementioned gases including other diluent/carrier gases and remain within the scope of the present disclosure.

The etchant source 120 includes an etchant 24 and is connected to the chamber arrangement 104, for example through an etchant supply valve 130, and is configured to flow the etchant 24 to the chamber arrangement 104. In this respect the etchant supply valve 130 may in turn be operatively associated with the controller 108, may be incorporated in an MFC device, and may cooperate with one or more of a mass flow meter and a diverter valve to flow the etchant 24 to the chamber arrangement 104. In further respect, the etchant source 120 may be configured to intermix the etchant 24 with the one or more of the silicon-containing precursor 16, the germanium-containing precursor 18, and the boron-containing precursor 20 to co-flow the etchant 24 with one or more of the aforementioned precursors to the chamber arrangement 104. In certain examples the etchant may include a halide-containing material, such chlorine (Cl₂) gas and/or hydrochloric (HCl) acid. As will be appreciated by those of skill in the art in view of the present disclosure, other etchants may be employed and remain within the scope of the present disclosure.

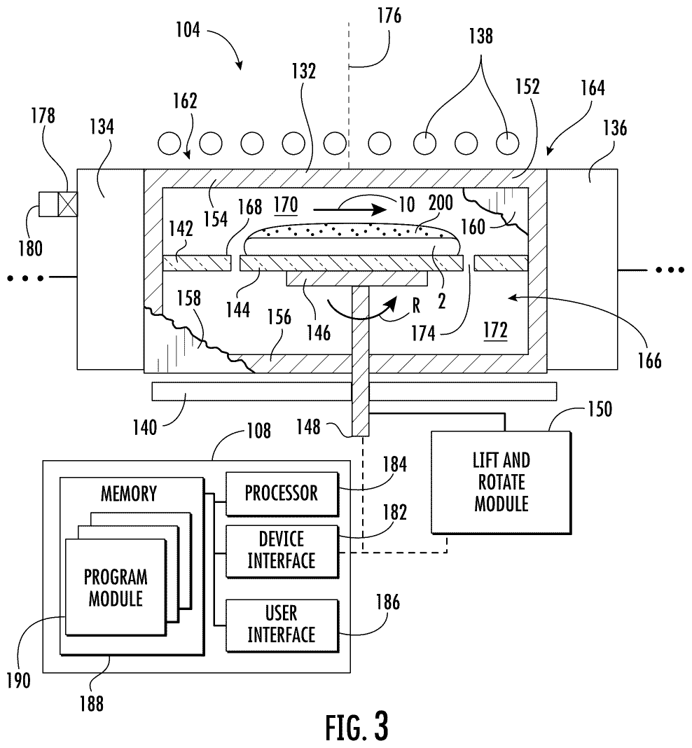

With reference to FIG. 3, the chamber arrangement 104 and the controller 108 are shown according to an example of the present disclosure. In the illustrated example the chamber arrangement 104 has a single-wafer cross flow arrangement and in this respect includes a chamber body 132, an injection flange 134, and an exhaust flange 136. In further respect, the chamber arrangement 104 may also include an upper heater element array 138, a lower heater element array 140, a divider 142, a substrate support 144, a support member 146, a shaft member 148, and a lift and rotate module 150. Although shown and described herein as including certain elements and having a specific arrangement, it is to be understood and appreciated that the chamber arrangement 104 may have a different arrangement or include additional elements and/or exclude elements shown and described herein and remain within the scope of the present disclosure.

The chamber body 132 is formed from a transparent material 152 (e.g., transmissive to electromagnetic radiation within an infrared waveband) and has an upper wall 154, a lower wall 156, a first sidewall 158, and a second sidewall 160. The upper wall 154 extends between an injection end 162 and a longitudinally opposite exhaust end 164 of the chamber body 132. The lower wall 156 is spaced apart from the upper wall 154 by an interior 166 of the chamber body 132, extends between the injection end 162 and the exhaust end 164 of the chamber body 132, and is coupled to the upper wall 154 by the first sidewall 158 and the second sidewall 160. In certain examples, the transparent material 152 may include a ceramic material such as quartz, fused silica, and sapphire. In accordance with certain examples, the chamber body 132 may include a plurality of external ribs extending about an exterior of the chamber body 132 and longitudinally spaced apart from one another between the injection end 162 and the exhaust end 164 of the chamber body 132. Although shown and described herein as having generally planar shapes, it is to be understood and appreciated that either (or both) the upper wall 154 and the lower wall 156 may have define an arcuate profile and/or have a generally dome-like shape and remain within the scope of the present disclosure.

The injection flange 134 abuts the injection end 162 of the chamber body 132 and couples the precursor supply arrangement 102 to the chamber body 132. The injection flange 134 is further configured to communicate the precursor 10 provided by the precursor supply arrangement 102 (shown in FIG. 1) to the interior 166 of the chamber body 132, for example to provide lateral (side-to-side) mass flow control of precursor 10. The exhaust flange 136 abuts the exhaust end 164 of the chamber body 132, couples the chamber body 132 to the exhaust arrangement 106, and is configured to communicate the residual precursor and/or reaction products 12 issued by chamber arrangement 104 during forming of the semiconductor structure 200 to the exhaust arrangement 106 (shown in FIG. 1).

The upper heater element array 138 is supported above the upper wall 154 of the chamber body 132 and is configured to communicate heat into the interior 166 of the chamber body 132 through the upper wall 154 of the chamber body 132, for example, using electromagnetic radiation within an infrared waveband transmitted by the transparent material 152 forming the upper wall 154 of the chamber body 132 to radiantly communicate heat into the interior 166 of the chamber body 132. The lower heater element array 140 is similar to the upper heater element array 138, is additionally supported below the lower wall 156 of the chamber body 132 and is configured to communicate heat into the interior 166 of the chamber body 132 through the lower wall 156 of the chamber body 132. In certain examples the upper heater element array 138 may include a plurality of upper linear lamps, the lower heater element array 140 may include a plurality of lower linear lamps, and the plurality of lower linear lamps may be orthogonal relative to the plurality of upper linear lamps. In accordance with certain examples, the plurality of upper linear lamps may extend laterally between the first sidewall 158 and the second sidewall 160, the plurality of linear lamps longitudinally spaced apart from one another between the injection end 162 and the exhaust end 164 of the chamber body 132. It is also contemplated that the plurality of upper linear lamps may extend longitudinally between the injection end 162 and the exhaust end 164 of the chamber body 132 and be laterally spaced apart from one another between the first sidewall 158 and the second sidewall 160 and remain within the scope of the present disclosure. As will be appreciated by those of skill in the art in view of the present disclosure, either (or both) the upper heater element array 138 and the lower heater element array 140 may include bulb or spot lamp-type heater elements and remain within the scope of the present disclosure.

The divider 142 is formed from an opaque material 168 (e.g., a material opaque to electromagnetic radiation within an infrared waveband), is fixed within the interior 166 of the chamber body 132 and divides the interior 166 of the chamber body 132 into an upper chamber 170 and a lower chamber 172. The divider 142 further defines an aperture 174, the aperture 174 in turn fluidly coupling the upper chamber 170 to the lower chamber 172 of the interior 166 of the chamber body 132. The substrate support 144 is supported for rotation R about a rotation axis 176 extending through the aperture 174, is arranged at least partially within the aperture 174, and is configured to support the substrate 2 during the forming of the semiconductor structure 200 onto the substrate 2. In this respect it is contemplated that the substrate support 144 may be formed from an opaque material (e.g., the opaque material 168) and be optically coupled to at least one of the upper heater element array 138 and the lower heater element array 140 by the upper wall 154 and the lower wall 156 of the chamber body 132, respectively. In certain examples, the opaque material 168 may include a carbonaceous material and/or silicon carbide.

The support member 146 is arranged along the rotation axis 176 and within the lower chamber 172 of the chamber body 132, is fixed in rotation relative to the substrate support 144 and couples the substrate support 144 to the shaft member 148. The shaft member 148 is fixed in rotation relative to the support member 146, extends through the lower wall 156 of the chamber body 132 and into the environment external to the chamber body 132, and couples the substrate support 144 to the lift and rotate module 150 through the support member 146. The lift and rotate module 150 is operably connected to the substrate support 144 and is configured to rotate the substrate support 144 about the rotation axis 176 during forming of the semiconductor structure 200 on the substrate 2. The lift and rotate module 150 may be further configured to seat and unseat substrates (e.g., the substrate 2) on the substrate support 144, for example, in cooperation with a gate valve 178 and substrate transfer robot 180. In certain examples, either (or both) the support member 146 and the shaft member 148 may be formed from a transparent material, such as the transparent material 152.

In the illustrated example the controller 108 includes a device interface 182, a processor 184, a user interface 186, and a memory 188. The device interface 182 couples the controller 108 to one or more of the precursor supply arrangement 102, the chamber arrangement 104, and the exhaust arrangement 106, for example, through the wired or wireless link 110. The processor 184 is disposed in communication with the device interface 182 and the memory 188, and is operably connected to the user interface 186, for example, to receive input and/or provide user output therethrough. The memory 188 includes a non-transitory machine-readable medium having a plurality of program modules 190 recorded thereon that, when read by the processor 184, cause the processor 184 to execute certain operations. Among the operations are operations of a method 400 (shown in FIG. 9) of making a semiconductor structure, e.g., the semiconductor structure 200, as will be described. Although shown and described herein as including certain elements and having a specific arrangement in the illustrated example, it is to be understood and appreciated that the controller 108 may include additional elements and/or exclude elements shown and described herein, or have a different architecture (e.g., a distributed computing architecture), and remain within the scope of the present disclosure.

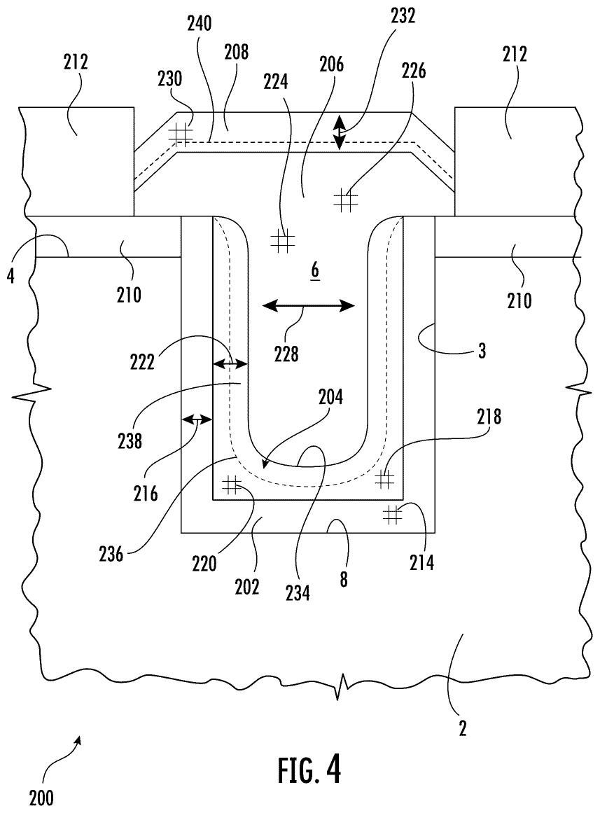

With reference to FIG. 4, the semiconductor structure 200 is shown. In the illustrated example the semiconductor structure 200 overlays the substrate 2 and includes a silicon germanium (SiGe) layer 202, a first boron-doped silicon germanium (SiGe:B) 204, and a second SiGe:B layer 206. The semiconductor structure 200 also includes a SiGe intermediate layer 240, a boron-doped silicon (Si:B) layer 208, a channel 210, and a gate 212. The substrate 2 defines a trench 6 within the upper surface 4 of the substrate 2. The trench 6 has a bottom 8 and a sidewall 3, extends into the bulk material forming the substrate 2, and defined at least in part by a silicon (Si) containing material. It is contemplated that the channel 210 overlay the upper surface 4 of the substrate 2 and be laterally offset from the trench 6. It is also contemplated that the gate 212 overlay (e.g., be deposited onto) the channel 210, also be laterally offset from the trench 6, and be configured to cooperate with the channel 210 within a semiconductor device including the semiconductor structure 200, such as a finned field-effect-transistor (finFET) semiconductor device, a GAA semiconductor device, or 3D DRAM semiconductor device.

The SiGe layer 202 is arranged (e.g., formed or deposited) within the trench 6, overlays the bottom 8 and the sidewall 3 of the trench 6, and may be conformally deposited onto the bottom 8 and the sidewall 3 of the trench 6. In certain examples the SiGe layer 202 may have a SiGe layer germanium concentration 214 that is between about 5% and about 20%, for example between about 5% and about 10%, or between about 10% and about 15%, or even between about 15% and about 20% germanium concentration. In accordance with certain examples, the SiGe layer 202 may have a SiGe layer thickness 216 that is between about 50 angstroms and about 450 angstroms, for example between about 50 angstroms and about 200 angstroms, or between about 200 angstroms and about 350 angstroms, or even between about 350 angstroms and about 600 angstroms in thickness. It is contemplated that the SiGe layer 202 may be epitaxial (e.g., monocrystalline) with the silicon-containing material bounding the trench 6. It is also contemplated that the SiGe layer 202 may consist of or consist essentially of silicon germanium, and that the SiGe layer 202 may be compositionally uniform or compositionally graded.

The first SiGe:B layer 204 may arranged (e.g., formed or deposited) within the trench 6, overlay the SiGe layer 202, and be conformally deposited onto the SiGe layer 202. In certain examples, the first SiGe:B layer 204 may have a first SiGe:B layer germanium concentration 218 that is between about 15% and about 35%. For example, the first SiGe:B layer germanium concentration 218 may be between about 15% and about 25%, or between about 25% and about 35%, or even between about 35% and about 45% germanium. In accordance with certain examples, the first SiGe:B layer 204 may have a first SiGe:B layer boron concentration 220 that is between about 5e¹⁸ atoms/cubic centimeter (cm³) and about 1e²⁰ atoms/cm³. In this respect the first SiGe:B layer may have a first SiGe:B boron concentration 220 that is between about 5e18atoms/cm3 and about 5e¹⁹ atoms/cm³, or between about 5e¹⁹ atoms/cm³ and about 1e²⁰ atoms/cm³, or even between about 1e²⁰ atoms/cm³ and about 5e²⁰ atoms/cm³. It is contemplated that the first SiGe:B layer 204 may have a first SiGe:B layer thickness 222 that is between about 200 angstroms and about 500 angstroms, for example between about 200 angstroms and about 350 angstroms, or between about 350 angstroms and about 500 angstroms, or even between about 500 angstroms about 650 angstroms. It is also contemplated that the first SiGe:B layer 204 may be epitaxial (e.g., monocrystalline) with the silicon germanium material forming the SiGe layer 202, that the first SiGe:B layer 204 may consist of or consist essentially of a boron-doped silicon germanium material, and the first SiGe layer may by compositionally uniform or compositionally graded with respect to either (or both) germanium concentration and boron concentration.

The second SiGe:B layer 206 is arranged at least partially within the trench 6, overlays the first SiGe:B layer 204, and may be conformally deposited onto the first SiGe:B layer 204. The second SiGe:B layer 206 may further protrude from the trench 6 and above the upper surface 4 of the substrate 2, and laterally separate the channel 210 from a channel of an adjacent semiconductor device. The second SiGe:B layer 206 may further separate (at least in part) the channel 210 from a channel of the adjacent semiconductor device and protrude from the trench 6 in a direction opposite the channel 210. In certain examples the second SiGe:B layer 206 may have a second SiGe:B layer germanium concentration 224 that is between about 30% and about 75%, for example between about 30% and about 45%, or between about 45% and about 60%, or even between about 60% and about 75% germanium. In accordance with certain examples, the second SiGe:B layer 206 may have a second SiGe:B layer boron concentration 226. The second SiGe:B boron concentration layer may be between about 1e¹⁹ atoms/cm³ and about 5e²⁰ atoms/cm³, for example between about 1e¹⁹ atoms/cm³ and about 5e¹⁹ atoms/cm³, or between about 5e¹⁹ atoms/cm³ and about 1e²⁰ atoms/cm³, or even between about 1e²⁰ atoms/cm³ and about 5e²⁰ atoms per/cm³ boron concentration. It is contemplated that the second SiGe:B layer 206 may have a second SiGe:B layer thickness 228 that is between about 300 angstroms and about 900 angstroms. In this respect the second SiGe:B layer thickness 228 may be between about 300 angstroms and about 500 angstroms, or between about 500 angstroms and about 700 angstroms, or even between about 700 angstroms about 900 angstroms. It is also contemplated that the second SiGe:B layer 206 may be epitaxial (e.g., monocrystalline) with the boron-doped silicon germanium material forming the first SiGe:B layer 204, and that the second SiGe:B layer 206 may consist of or consist essentially of a boron-doped silicon germanium material differing in composition from that of the first SiGe:B layer 204.

The SiGe intermediate layer 240 overlays the second SiGe:B layer 206 and may be conformally deposited onto the second SiGe:B layer 206. In certain examples of the present disclosure the SiGe intermediate layer 240 may include substantially no boron. In accordance with certain examples, the SiGe intermediate layer 240 may consist of or consist essentially of SiGe. It is contemplated that the SiGe intermediate layer 240 may have a thickness that is less than a thickness of the second SiGe:B layer 206. It is also contemplated that the SiGe intermediate layer 240 may have a thickness that is less than a thickness of the SiB layer 208.

The Si:B layer 208 overlays the second SiGe:B layer 206, may further overlay the SiGe intermediate layer 240, and may be conformally deposited onto the second SiGe:B layer 206. In this respect the Si:B layer 208 may be arranged (e.g., formed or deposited) at least in part above the trench 6, the SiGe:B layer 208 laterally separating (at least in part) the gate 212 from the gate includes the semiconductor device adjacent to the gate 212. In certain examples the Si:B layer 208 may have an Si:B layer boron concentration 230 that is between about 1e²⁰ atoms/cm³ and about 1e²² atoms/cm³. For example, the Si:B layer boron concentration 230 may be between about 1e²⁰ atoms/cm³ and about 5e²⁰ atoms/cm³, or between about 5e²⁰ atoms/cm³ and about 1e²¹ atoms/cm³, or even between about 1e²¹ atoms/cm³ and about 5e²¹ atoms/cm³. In accordance with certain examples, the Si:B layer 208 may have a Si:B layer thickness 232, for example a Si:B layer thickness 232 that is between about 25 angstroms and about 250 angstroms. In this respect the Si:B layer thickness 232 may be between about 25 angstroms and about 100 angstroms, or between about 100 angstroms and about 175 angstroms, or even between about 175 angstroms and about 250 angstroms. It is contemplated that the Si:B layer 208 may be epitaxial (e.g., monocrystalline) with the boron-doped silicon germanium material forming the second SiGe:B layer 206. It is also contemplated that the Si:B layer 208 may consist of or consist essentially of a boron-doped silicon material.

In certain examples, the second SiGe:B layer thickness 228 may be greater than the first SiGe:B layer thickness 222. The first SiGe:B layer thickness 222 may be greater than the SiGe layer thickness 216, and that the Si:B layer thickness 232 may be less than the second SiGe:B layer thickness 228. In accordance with certain examples, the second SiGe:B layer germanium concentration 224 may be greater that the first SiGe:B layer germanium concentration 218. The first SiGe:B layer germanium concentration 218 may be greater than the SiGe layer germanium concentration 214. It is also contemplated that, in accordance with certain examples, the second SiGe:B layer boron concentration 226 may be greater than the first SiGe:B layer boron concentration 220, and that the Si:B layer boron concentration 230 may be greater than the second SiGe:B layer boron concentration 226. As will be appreciated by those of skill in the art in view of the present disclosure, semiconductor structures 200 having these compositions may exert suitable compressive stress on the channel 210 such that semiconductor devices formed using the semiconductor structure 200 have advantageous characteristics (e.g., channel resistivity and/or device speed).

As has been explained above, layer constituents having greater affinity for affinity for incorporation at the growth face of a depositing than other layer constituents can, in some deposition processes, induce concentration variation within a semiconductor structure being formed from the layer. In this respect applicant has come to appreciate that boron may, absent countermeasures, aggregate at a first SiGe:B layer-to-second SiGe:B layer interface 234 defined between the first SiGe:B layer 204 and the second SiGe:B layer 206. Without being bound by a particular theory or mode of operation, applicant believes that available boron atoms resident within the process environment will outcompete (and thereby preferentially incorporate) into semiconductor structures like the semiconductor structure 200 over available germanium and silicon atoms, potentially causing boron to accumulate at the first SiGe:B layer-to-second SiGe:B layer interface 234 and altering the electrical properties of the semiconductor structure 200. To avoid such boron aggregation, and to ensure that boron concentration at the first SiGe:B layer-to-second SiGe:B layer interface 234 does not exceed that second SiGe:B layer boron concentration, the semiconductor structure 200 is formed by staggering the increase in flow of the boron-containing precursor 20 between a first boron-containing precursor mass flow rate used to deposit the first SiGe:B layer 204 and a second boron-containing precursor mass flow rate used to form the second SiGe:B layer 206 with a staggered increase of the boron-containing precursor mass flow rate to an intermediate boron-containing precursor mass flow rate during deposition of the first SiGe:B layer 204. The staggered increase throttles the amount of available boron atoms at the growth face of the semiconductor structure 200 during the formation of the first SiGe:B layer 204, ensuring that the available boron atoms do not outcompete increased (in relative terms) available germanium atoms provided to the growth face to initiate deposition of the second SiGe:B layer 206. Advantageously, the staggered increase avoids the need to cease deposition of the first SiGe:B layer 204 prior to the second SiGe:B layer 206. To further advantage, the staggered increase imparts a partial compositional grading into the first SiGe:B layer 204, the first SiGe:B layer 204 having a first portion 236 bounding the SiGe layer 202, and a second portion 238 overlaying the first portion 236 and bounding the second SiGe:B layer 206, limiting stress at the first SiGe:B layer-to-second SiGe:B layer interface 234.

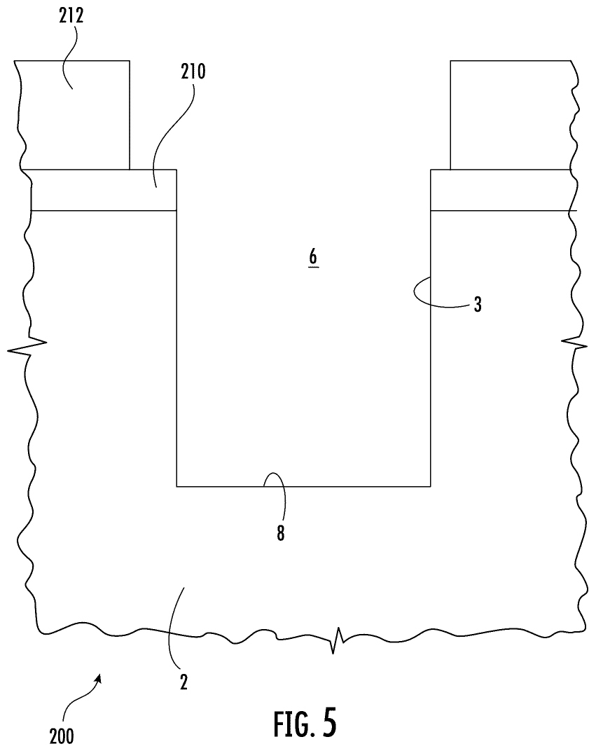

With reference to FIGS. 5-10, the semiconductor structure 200 is shown being sequentially formed according to the method 300 during a continuous process, for example, wherein precursor flow does not cease for purposes of managing boron aggregation at the first SiGe:B layer-to-second SiGe:B layer interface 234 (shown in FIG. 4). As shown in FIG. 5, forming the semiconductor structure 200 begins by seating the seating the substrate within a semiconductor processing system, e.g., the semiconductor processing system 100 (shown in FIG. 1). In this respect the gate valve 178 (shown in FIG. 3) may be opened such that the substrate transfer robot 180 (shown in FIG. 3) may advance an end effector into the substrate 2 into the upper chamber 170 of the chamber body 132 (shown in FIG. 3) to a location above the substrate support 144. The lift and rotate module 150 may then seat the substrate 2 on an upper surface of the substrate support 144, for example using a plurality of lift pins slidably received within the substrate support 144, and end effector thereafter withdrawn from the upper chamber 170 the chamber body 132. It is contemplated that the gate valve 178 then be closed, pressure within the interior 166 driven to a predetermined SiGe layer deposition pressure, the substrate heated to a predetermined SiGe deposition temperature, and the substrate 2 rotated about the rotation axis 176 (shown in FIG. 3). Driving pressure within the interior 166 of the chamber body 132 may be accomplished using a vacuum pump included in the exhaust arrangement 106 (shown in FIG. 1), for example in cooperation with a pressure control valve coupling the chamber arrangement 104 (shown in FIG. 1) to the exhaust arrangement 106. Heating of the substrate 2 to the predetermined SiGe layer deposition temperature may be accomplished radiantly, for example using the upper heater element array 138 (shown in FIG. 3) and/or the lower heater element array 140 (shown in FIG. 3). Rotating R the substrate 2 about the rotation axis 176 may be accomplished using the lift and rotate module 150 (shown in FIG. 3).

Deposition of the SiGe layer 202 may be accomplished by flowing the silicon-containing precursor 16 and the germanium-containing precursor 18 to the chamber arrangement 104 (shown in FIG. 3). It is contemplated that the injection flange 134 communicate the silicon-containing precursor 16 and the germanium-containing precursor 18 to the chamber body 132, and that the chamber body 132 flow the silicon-containing precursor 16 and the germanium-containing precursor 18 across the upper surface 4 of the substrate 2 as the substrate 2 rotates about the rotation axis 176 (shown in FIG. 3), exposing the substrate 2 to the silicon-containing precursor 16 and the germanium-containing precursor 18. As will be appreciated by those of skill in the art in view of the present disclosure, exposing the substrate 2 to the silicon-containing precursor 16 and the germanium-containing precursor 18 causes the SiGe layer 202 to deposit onto the substrate 2 according to the predetermined SiGe layer deposition temperature, the predetermined SiGe layer deposition pressure, mass flow rate of the silicon-containing precursor 16 and the germanium-containing precursor 18, and duration of exposure of the substrate 2 to the silicon-containing precursor 16 and the germanium-containing precursor 18.

In certain examples the predetermined SiGe layer deposition pressure may be between about 0.1 Torr and about 760 Torr. In this respect the SiGe layer deposition pressure may be between about 0.1 Torr and about 10 Torr, or between about 10 Torr and about 50 Torr, or even between about 50 Torr and about 760 Torr. In accordance with certain examples, the predetermined SiGe layer deposition temperature may be between about 400 degrees Celsius and about 1000 degrees Celsius. For example, the predetermined SiGe layer deposition temperature may be between about 400 degrees Celsius and about 600 degrees Celsius, or between about 600 degrees Celsius and about 800 degrees Celsius, or even between about 800 degrees Celsius and about 1000 degrees Celsius. It is contemplated that the SiGe layer deposition interval may be between about 5 seconds and about 30 seconds, for example between about 5 seconds and about 15 seconds, or between about 15 seconds and about 25 seconds, or even between about 25 seconds and about 35 seconds. It is also contemplated that the either (or both) the silicon-containing precursor 16 and the germanium-containing precursor 18 be intermixed with the diluent/carrier gas 22, and that the etchant 24 may be co-flowed with the silicon-containing precursor 16 and the germanium-containing precursor 18 through the upper chamber 170 of the chamber body 132.

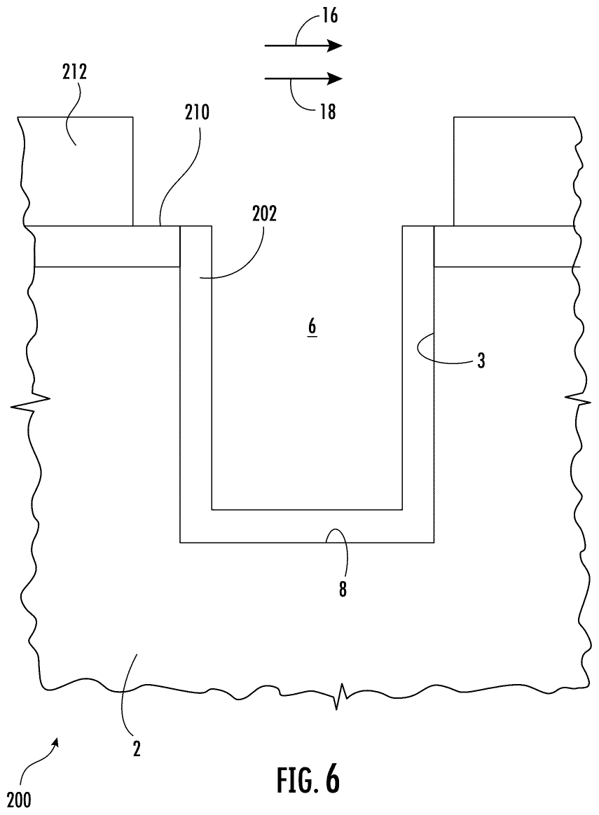

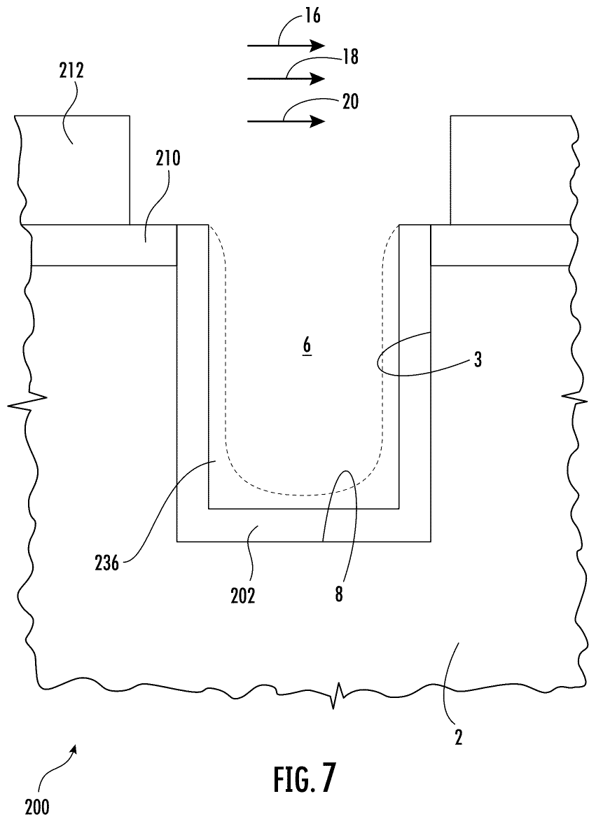

As shown in FIGS. 6 and 7, deposition of the first SiGe:B layer 204 may be accomplished by flowing (e.g., coincidently) the silicon-containing precursor 16, the germanium-containing precursor 18, and the boron-containing precursor 20 to the chamber arrangement 104 (shown in FIG. 3). In this respect it is contemplated that the precursor supply arrangement 102 (shown in FIG. 2) flow the silicon-containing precursor 16 to the chamber arrangement 104 at a first SiGe:B layer silicon-containing precursor mass flow rate, that the precursor supply arrangement 102 flow the germanium-containing precursor 18 to the chamber arrangement 104 a first SiGe:B layer germanium-containing precursor mass flow rate, and that the precursor supply arrangement 102 flow the boron-containing precursor 20 to the chamber arrangement 104 at a first SiGe:B layer first boron-containing precursor mass flow rate. It is contemplated that the injection flange 134 communicate the silicon-containing precursor 16, the germanium-containing precursor 18, and the boron-containing precursor 20 to the chamber body 132; and that the chamber body 132 in turn expose the upper surface 4 of the substrate 2 to the silicon-containing precursor 16, the germanium-containing precursor 18, and the boron-containing precursor 20 as the substrate 2 rotates about the rotation axis 176 (shown in FIG. 3). As will be appreciated by those of skill in the art in view of the present disclosure, exposing the substrate 2 to the silicon-containing precursor 16, the germanium-containing precursor 18, and the boron-containing precursor causes the first SiGe layer 204 to deposit onto the SiGe layer 202 according to the predetermined first SiGe:B layer deposition temperature; the predetermined first SiGe:B layer deposition pressure; the first SiGe:B layer silicon-containing precursor mass flow rate, the first SiGe:B layer germanium-containing precursor mass flow rate, and the first SiGe:B layer boron-containing precursor mass flow rate; and duration of a predetermined first SiGe:B layer deposition interval during which the substrate 2 (and thereby of the SiGe layer 202) is exposed to the silicon-containing precursor 16, the germanium-containing precursor 18, and the boron-containing precursor 20.

In certain examples the predetermined first SiGe:B layer deposition pressure may be between about 0.1 Torr and about 760 Torr. In this respect the predetermined first SiGe:B layer deposition pressure may be between about 0.1 Torr and about 10 Torr, or between about 10 Torr and about 50 Torr, or even between about 50 Torr and about 760 Torr. In accordance with certain examples, the predetermined first SiGe:B layer deposition temperature may be between about 400 degrees Celsius and about 1000 degrees Celsius. For example, the predetermined first SiGe:B layer deposition temperature may be between about 400 degrees Celsius and about 600 degrees Celsius, or between about 600 degrees Celsius and about 800 degrees Celsius, or even between about 800 degrees Celsius and about 1000 degrees Celsius. It is contemplated that the predetermined first SiGe:B layer deposition interval may be between about 50 seconds and about 450 seconds, for example between about 50 seconds and about 200 seconds, or between about 200 seconds and about 350 seconds, or even between about 350 seconds and about 500 seconds. It is also contemplated that one or more of the silicon-containing precursor 16, the germanium-containing precursor 18, and the boron-containing precursor 20 may be intermixed with the diluent/carrier gas 22 when flowed to the chamber arrangement 104 (shown in FIG. 1) during deposition of the first SiGe:B layer 204. It is further contemplated that the etchant 24 may be co-flowed with one or more of the silicon-containing precursor 16, the germanium-containing precursor 18, and the boron-containing precursor 20 with one another through the upper chamber 170 (shown in FIG. 3) of the chamber body 132 (shown in FIG. 3) during deposition of the first SiGe:B layer 204. It is further contemplated that the first SiGe:B layer 204 may be deposited continuously and without interruption, for example between completion of deposition of the SiGe layer 202 and beginning of deposition of the second SiGe:B layer 206.

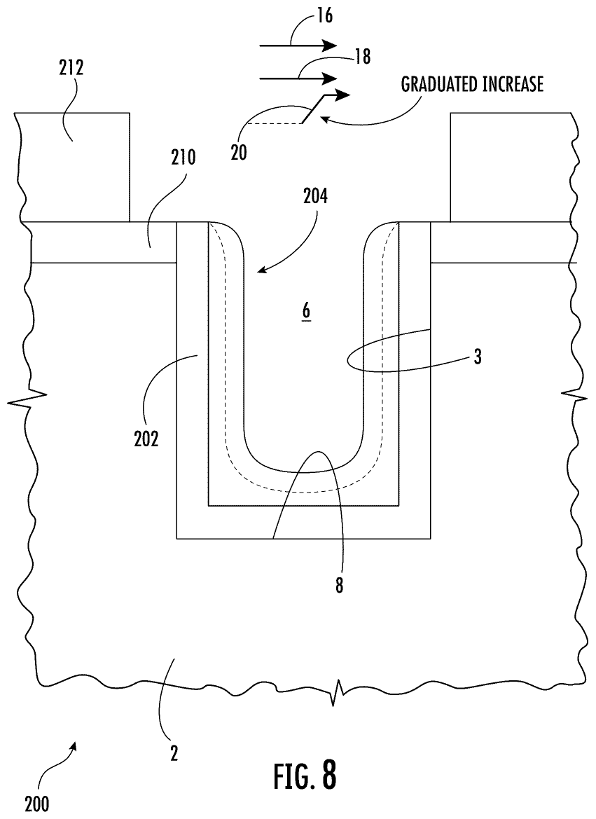

As shown in FIG. 8, deposition of the second SiGe:B layer 206 may be accomplished by flowing the silicon-containing precursor 16, the germanium-containing precursor 18, and the boron-containing precursor 20 to the chamber arrangement 104 (shown in FIG. 3). In this respect it is contemplated that the precursor supply arrangement 102 (shown in FIG. 2) flow of the silicon-containing precursor 16, the germanium-containing precursor 18, and the boron-containing precursor 20 to the chamber arrangement 104. The silicon-containing precursor 16 may be flowed to the chamber arrangement 104 at second SiGe:B layer silicon-containing precursor mass flow rate, the germanium-containing precursor 18 may be flowed to the chamber arrangement 104 at a second SiGe:B layer germanium mass flow rate, and the boron-containing precursor 20 flowed to the chamber arrangement 104 at a second SiGe:B layer boron-containing precursor flow rate. It is contemplated that the injection flange 134 communicate the silicon-containing precursor 16, the germanium-containing precursor 18, and the boron-containing precursor 20 to the chamber body 132, and that the chamber body 132 in turn expose the upper surface 4 of the substrate 2 to the silicon-containing precursor 16, the germanium-containing precursor 18, and the boron-containing precursor 20 as the substrate 2 rotates about the rotation axis 176 (shown in FIG. 3). As will be appreciated by those of skill in the art in view of the present disclosure, exposing the substrate 2 to the silicon-containing precursor 16, the germanium-containing precursor 18, and the boron-containing precursor causes the second SiGe:B layer 206 to deposit onto the first SiGe:B layer 204 according to the predetermined second SiGe:B layer deposition temperature; the predetermined second SiGe:B layer deposition pressure; the second SiGe:B layer silicon-containing precursor mass flow rate, the second SiGe:B layer germanium-containing precursor mass flow rate, and the second SiGe:B layer boron-containing precursor mass flow rate; and duration of a predetermined second SiGe:B layer deposition interval.

In certain examples the predetermined second SiGe:B layer deposition pressure may be between about 0.1 Torr and about 760 Torr. In this respect the second predetermined SiGe:B layer deposition pressure may be between about 0.1 Torr and about 10 Torr, or between about 10 Torr and about 50 Torr, or even between about 50 Torr and about 760 Torr. In accordance with certain examples, the predetermined second SiGe:B layer deposition temperature may be between about 400 degrees Celsius and about 1000 degrees Celsius. For example, the predetermined second SiGe:B layer deposition temperature may be between about 400 degrees Celsius and about 600 degrees Celsius, or between about 600 degrees Celsius and about 800 degrees Celsius, or even between about 800 degrees Celsius and about 1000 degrees Celsius. It is contemplated that the predetermined second SiGe:B layer deposition interval may be between about 100 seconds and about 400 seconds, for example between about 100 seconds and about 200 seconds, or between about 200 seconds and about 300 seconds, or even between about 300 seconds and about 400 seconds. It is also contemplated that one or more of the silicon-containing precursor 16, the germanium-containing precursor 18, and the boron-containing precursor 20 may be intermixed with the diluent/carrier gas 22 when flowed to the chamber arrangement 104 (shown in FIG. 1) during deposition of the second SiGe:B layer 206. It is further contemplated that the etchant 24 may be co-flowed with one or more of the silicon-containing precursor 16, the germanium-containing precursor 18, and the boron-containing precursor 20 with one another through the upper chamber 170 (shown in FIG. 3) of the chamber body 132 (shown in FIG. 3) during deposition of the second SiGe:B layer 206. In certain examples, the second SiGe:B layer 206 may be deposited continuously and without interruption, for example between completion of deposition of the first SiGe:B layer 204 and beginning of deposition of the Si:B layer 208 (or form definition of the first SiGe:B layer-to-second SiGe:B layer interface 234).

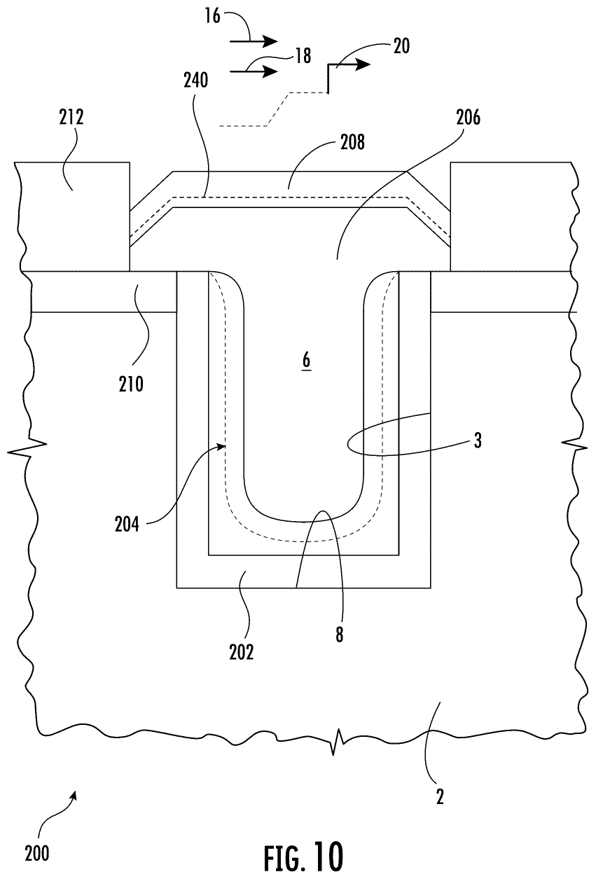

As shown in FIGS. 9 and 10, deposition of the Si:B layer 208 may be accomplished by flowing the silicon-containing precursor 16 and the boron-containing precursor 20 to the chamber arrangement 104 (shown in FIG. 3). In this respect it is contemplated that the precursor supply arrangement 102 (shown in FIG. 2) may flow of the silicon-containing precursor 16 to the chamber arrangement 104 at a Si:B layer silicon-containing precursor mass flow rate and the boron-containing precursor 20 to the chamber arrangement 104 at a Si:B layer boron-containing precursor mass flow rate. It is contemplated that the injection flange 134 communicate the silicon-containing precursor 16 and the boron-containing precursor 20 received from the precursor supply arrangement 102 to the chamber body 132, and that the chamber body 132 in turn expose the second SiGe:B layer 206 to the silicon-containing precursor 16 and the boron-containing precursor 20 as the substrate 2 rotates about the rotation axis 176 (shown in FIG. 3). As will be appreciated by those of skill in the art in view of the present disclosure, exposing the second SiGe:B layer 206 to the silicon-containing precursor 16 and the boron-containing precursor 20 causes the Si:B layer 208 to deposit onto the second SiGe:B layer 206 according to the predetermined Si:B layer deposition temperature; the predetermined Si:B layer deposition pressure; the Si:B layer silicon-containing precursor mass flow rate and the Si:B layer boron-containing precursor mass flow rate; and duration of a Si:B layer deposition interval.

In certain examples the predetermined Si:B layer deposition pressure may be between about 0.1 Torr and about 760 Torr. In this respect the predetermined Si:B layer deposition pressure may be between about 0.1 Torr and about 10 Torr, or between about 10 Torr and about 50 Torr, or even between about 50 Torr and about 760 Torr. In accordance with certain examples, the predetermined Si:B layer deposition temperature may be between about 400 degrees Celsius and about 1000 degrees Celsius. For example, the predetermined Si:B layer deposition temperature may be between about 400 degrees Celsius and about 600 degrees Celsius, or between about 600 degrees Celsius and about 800 degrees Celsius, or even between about 800 degrees Celsius and about 1000 degrees Celsius. It is contemplated that the predetermined Si:B layer deposition interval may be between about 100 seconds and about 400 seconds, for example between about 100 seconds and about 200 seconds, or between about 200 seconds and about 300 seconds, or even between about 300 seconds and about 400 seconds. It is also contemplated that one or more of the silicon-containing precursor 16 and the boron-containing precursor 20 may be intermixed with the diluent/carrier gas 22 when flowed to the chamber arrangement 104 (shown in FIG. 1) during deposition of the Si:B layer 208. It is further contemplated that the etchant 24 may be co-flowed with one or more of the silicon-containing precursor 16 and the boron-containing precursor 20 with one another through the upper chamber 170 (shown in FIG. 3) of the chamber body 132 (shown in FIG. 3) during deposition of the Si:B layer 208.

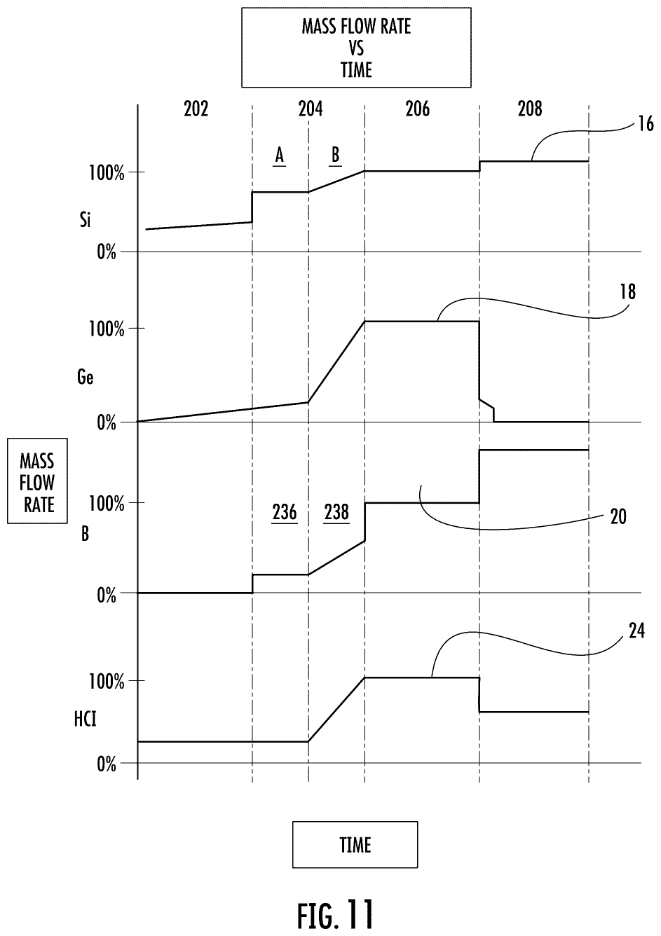

With reference to FIG. 11 and with continuing reference to FIGS. 6 and 7, it is contemplated that the boron-containing precursor 20 flowed to the chamber arrangement 104 (shown in FIG. 3) at the first SiGe:B layer first boron-containing precursor mass flow rate deposit the first portion 236 of the first SiGe:B layer 204. It is also contemplated that mass flow rate of the boron-containing precursor 20 thereafter (and during deposition of the first SiGe:B layer 204) be increased to a first SiGe:B boron layer intermediate boron-containing precursor flow rate, and that the second portion 238 of the first SiGe:B layer 204 be deposited using the boron-containing precursor 20 flowed to the chamber arrangement 104 at the first SiGe:B layer intermediate boron-containing precursor flow rate. It is further contemplated that mass flow rate of the boron-containing precursor 20 flowed to the chamber arrangement 104 be further increased to the first SiGe:B layer second boron-containing precursor mass flow rate, and that the second SiGe:B layer 206 be deposited onto the first SiGe:B layer 204 layer using the boron-containing precursor 20 flowed to the chamber arrangement 104 at the first SiGe:B layer second boron-containing precursor mass flow rate. Advantageously, increasing mass flow rate of the boron-containing precursor 20 to the first SiGe:B layer intermediate boron-containing precursor mass flow rate limits boron concentration at the first SiGe:B layer-to-second SiGe:B layer interface 234 defined between the first SiGe:B layer and the second SiGe:B layer to less than the boron concentration within the second SiGe:B layer 206, ensuring reliability of semiconductor devices formed using the semiconductor structure 200.

As shown in FIG. 11, the first portion 236 of the first SiGe:B layer 204 may be formed during a first SiGe:B layer first portion deposition interval A, and the second portion 238 of the first SiGe:B layer 204 may be formed during a first SiGe:B layer second portion deposition interval B. It is contemplated that the first SiGe:B layer second portion deposition interval may be shorter than the first SiGe:B layer first portion deposition interval. In this respect first SiGe:B layer second portion deposition interval may be between about 10% and about 40% of the first SiGe:B layer first portion deposition interval, for example between about 10% and about 20%, or between 20% and about 30%, or even between about 30% and about 40% of the first SiGe:B layer first portion deposition interval. It also contemplated that the second SiGe:B layer second portion deposition interval may be longer than the first SiGe:B layer first portion deposition interval. For example, the first SiGe:B layer second portion deposition interval may be between about 110% and about 140% of the first SiGe:B layer first portion deposition interval, such as between about 110% and about 120%, or between 120% and about 130%, or even between about 130% and about 140% of the first SiGe:B layer first portion deposition interval. The first SiGe:B layer boron-containing precursor mass flow rate may be substantially constant during the first SiGe:B layer first portion deposition interval. The first SiGe:B layer boron-containing precursor mass flow rate may be substantially constant during the first SiGe:B layer second portion deposition interval. In further examples the first SiGe:B layer boron-containing precursor mass flow rate may progressively increase during the first SiGe:B layer second portion deposition interval.

In certain examples mass flow rate of the boron-containing precursor 20 may be increased during only the first SiGe:B layer second portion deposition interval B. In this respect the first SiGe:B layer intermediate boron-containing precursor mass flow rate may be between about 110% and about 200% of the first SiGe:B layer first boron-containing precursor mass flow rate. In accordance with certain examples mass flow rate of the boron-containing precursor 20 may be increased during definition of (or to define) the first SiGe:B layer-to-second SiGe:B layer interface 234 (shown in FIG. 4). For example, mass flow rate of the boron-containing precursor 20 may be increased stepwise from the first SiGe:B layer intermediate boron-containing precursor mass flow rate to the first SiGe:B layer second boron-containing precursor mass flow rate. In this respect the first SiGe:B layer second boron-containing precursor may be between about 150% and about 250% of the first SiGe:B layer intermediate boron-containing precursor mass flow rate. Advantageously, this enables mass flow rate of the silicon-containing precursor 16 and the germanium-containing precursor 18 to be ramped during the first SiGe:B second portion deposition interval B to compensate for ramping of mass flow rate of the boron-containing precursor 20 during the first SiGe:B layer second portion deposition interval B (limiting or eliminating boron concentration at the first SiGe:B layer-to-second SiGe:B layer interface 234) while enabling composition of the first SiGe:B layer 204 to remain substantially uniform throughout the thickness of the SiGe:B layer 204.

In certain examples, a ratio of the germanium-containing precursor 18 to the silicon-containing precursor 16 may be increased during deposition of the second portion 238 of the first SiGe:B layer 204, for example during the first SiGe:B layer second portion deposition interval. The ratio increase may be effected by flowing the germanium-containing precursor 18 to the chamber arrangement 104 (shown in FIG. 1) at a first SiGe:B layer first germanium-containing precursor mass flow rate during deposition of the first portion 236 of the first SiGe:B layer 204, increasing mass flow rate of the germanium-containing precursor 18 from the first SiGe:B layer first germanium-containing precursor mass flow rate to a first SiGe:B layer second germanium-containing precursor mass flow rate during deposition of the second portion 238 of the first SiGe:B layer 204, and flowing the germanium-containing precursor 18 to the chamber arrangement 104 at a first SiGe:B layer second germanium-containing precursor mass flow rate during deposition of the second portion 238 of the second SiGe:B layer 206. In this respect the first SiGe:B layer second germanium-containing precursor mass flow rate may be between about 150% and about 400% of the first SiGe:B layer first germanium-containing precursor mass flow rate, for example between about 150% and about 250%, or between about 250% and about 350%, or even between about 350% and about 400% of the first SiGe:B layer first germanium-containing precursor mass flow rate. It is contemplated that the first SiGe:B layer germanium-containing precursor mass flow rate may remain substantially constant during deposition of the second SiGe:B layer 206. It is also contemplated that the mass flow rate of the germanium-containing precursor 18 may remain constant during definition of the first SiGe:B layer-to-second SiGe:B layer interface 234, for example by increasing mass flow rate of the germanium-containing precursor 18 step-wise at the end of the first SiGe:B layer second portion deposition interval. As will be appreciated by those of skill in the art in view of the present disclosure, first SiGe:B layer second germanium-containing precursor mass flow rates within these ranges can ensure continuous growth of the first SiGe:B layer 204 and the second SiGe:B layer 206 (and/or during definition of the first SiGe:B layer-to-second SiGe: layer interface 234) by throttling available germanium atoms at the growth face of the semiconductor structure 200 in amounts sufficient to offset increase in numbers of boron atoms at the growth face of the semiconductor structure 200.

In accordance with certain examples, the ratio increase may be effected by flowing the silicon-containing precursor 16 to the chamber arrangement 104 (shown in FIG. 1) at a first SiGe:B layer first silicon-containing precursor mass flow rate during deposition of the first portion 236 of the first SiGe:B layer 204, increasing mass flow rate of the silicon-containing precursor 16 from the first SiGe:B layer first silicon-containing precursor mass flow rate to a first SiGe:B layer second silicon-containing precursor mass flow rate during deposition of the second portion 238 of the first SiGe:B layer 204, and thereafter flowing the silicon-containing precursor 16 to the chamber arrangement 104 at a first SiGe:B layer second silicon-containing precursor mass flow rate during deposition of the second portion 238 of the second SiGe:B layer 206. In this respect the first SiGe:B layer second silicon-containing precursor mass flow rate may be between about 105% and about 125% of the first SiGe:B layer first silicon-containing precursor mass flow rate, for example between about 105% and about 110%, or between about 110% and about 120%, or even between about 120% and about 125% of the first SiGe:B layer first silicon-containing precursor mass flow rate. It is contemplated that the first SiGe:B layer second silicon-containing precursor mass flow rate may remain substantially constant during deposition of the second SiGe:B layer 206. It is also contemplated that the mass flow rate of the silicon-containing precursor 16 may remain substantially constant during definition of the first SiGe:B layer-to-second SiGe:B layer interface 234, for example by increasing mass flow rate of the silicon-containing precursor 16 step-wise at the end of the first SiGe:B layer second portion deposition interval. As will also be appreciated by those of skill in the art in view of the present disclosure, first SiGe:B layer second silicon-containing precursor mass flow rates within these ranges can ensure continuous growth of the first SiGe:B layer 204 and the second SiGe:B layer 206 (and/or during definition of the first SiGe:B layer-to-second SiGe: layer interface 234) by also throttling available silicon atoms at the growth face of the semiconductor structure 200 in amounts sufficient to offset increase in numbers of boron atoms at the growth face of the semiconductor structure 200.

In certain examples the etchant 24 may be flowed to the chamber arrangement 104 (shown in FIG. 1) at a first SiGe:B layer first etchant mass flow rate during deposition of the first portion 236 of the first SiGe:B layer 204. Mass flow rate of the etchant 24 may be increased to a first SiGe:B layer second etchant mass flow rate during deposition of the second portion 238 of the first SiGe:B layer 204, and the etchant 24 be flowed to the chamber arrangement 104 at the first SiGe:B layer second etchant mass flow rate during deposition of the second SiGe:B layer 206. In this respect the first SiGe:B layer second etchant mass flow rate may be between about 150% and about 600% of the first SiGe:B layer first etchant mass flow rate, for example between about 150% and about 300%, or between about 300% and about 450%, or even between about 450% and about 600% of the first SiGe:B layer first etchant mass flow rate. As will be appreciated by those of skill in the art in view of the present disclosure, first SiGe:B layer second etchant mass flow rates can continue selectivity of deposition during the first SiGe:B layer second portion deposition interval, and/or during deposition of the second SiGe:B layer, during the aforementioned increase in ratio of the germanium-containing precursor 18 provided to the chamber arrangement 104 during deposition of the second portion 238 of the first SiGe:B layer 204 and/or deposition of the second SiGe:B layer 206.

In certain examples a SiGe intermediate layer 240 (shown in FIG. 4) may be deposited onto the second SiGe:B layer 206 prior to deposition of the Si:B layer 208. In this respect it is contemplated that, while continuing to flow the silicon-containing precursor 16, flow of the boron-containing precursor 20 to the chamber arrangement 104 (shown in FIG. 1) may be reduced (or cease entirely). Flow of the germanium-containing precursor 18 to the chamber arrangement 104 may be reduced in concert (e.g., simultaneously) with the reducing (or ceasing entirely) flow of the boron-containing precursor 20 to the chamber arrangement 104. Flow of the silicon-containing precursor 16 and the germanium-containing precursor 18 without flow of the boron-containing precursor 20 may continue for a relatively short deposition interval, for example for a deposition interval shorter than both that of the second SiGe:B layer 206 and the Si:B layer 208, such that aa thickness of the SiGe intermediate layer 240 is less than that of the second SiGe:B layer 206 or even thinner than the Si:B layer 208. Deposition of the Si:B may then begin by restoring flow of the boron-containing precursor 20 to the chamber body 132, for example at a flow rate greater than that flowed during deposition of the second SiGe:B layer 206. Advantageously, deposition of the intermediate SiGe layer 240 may promote nucleation of constituent precursor of the Si:B layer 208 onto the semiconductor structure 200, for example by limiting (or eliminating) the relatively high germanium concentration (e.g., between 30% and about 60%) in the second SiGe:B layer 206 could otherwise have on nucleation of constituent precursors of the subsequently deposition Si:B layer 208 onto the semiconductor structure 200.

In certain examples the etchant 24 may be flowed to the chamber arrangement 104 (shown in FIG. 1) during deposition of the SiGe intermediate layer 240. In this respect flow of the etchant 24 may be reduced in concert (e.g., simultaneously) with the reduction in flow of the germanium-containing precursor 18 to the chamber arrangement 104 and in concert (e.g., simultaneously) with cessation of the boron-containing precursor 20 to the chamber arrangement 104, for example to exclude substantially all boron from the SiGe intermediate layer 240. Advantageously, this may prevent boron segregation at the interface of the second SiGe:B layer 206 and the Si:B layer 208 and thereby any influence that segregated boron at the interface of the second SiGe:B layer 206 and the Si:B layer 210 could otherwise have on the structure of the Si:B layer 201. To further advantage, flow rate of the etchant 24 may be less than flow rate of the etchant 24 provided to the chamber arrangement 104 during deposition of both the second SiGe:B layer 206 and the Si:B layer 208, limiting tendency of the etchant 24 to etch back the second SiGe:B layer 206 while retaining the aforementioned beneficial avoidance of boron segregation at the interface of the second SiGe:B layer 206 to the Si:B layer 208.

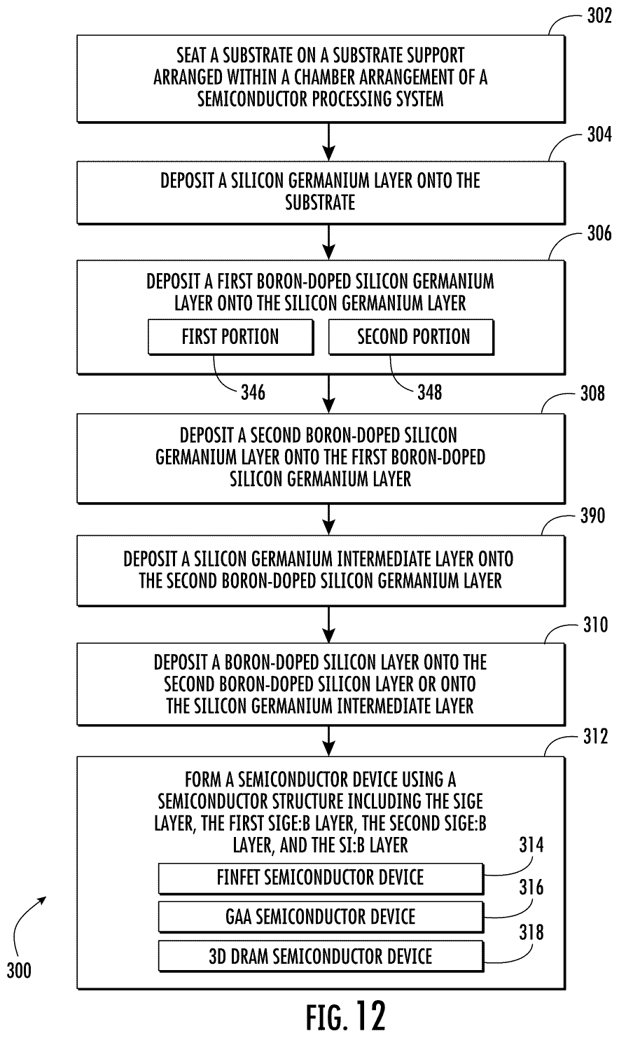

With reference to FIGS. 12-16, the method 300 of forming a semiconductor structure, e.g., the semiconductor structure 200 (shown in FIG. 1), is shown. As shown in FIG. 12, the method 300 includes seating a substrate on a substrate support arranged within a chamber arrangement of semiconductor processing system, e.g., the substrate 2 (shown in FIG. 1) within the semiconductor processing system 100 (shown in FIG. 1), as shown with box 302. A SiGe layer is deposited onto the substrate, e.g., the SiGe layer 202 (shown in FIG. 4), as shown with box 304; a first SiGe:B layer is deposited onto the SiGe layer, e.g., the first SiGe:B layer 204 (shown in FIG. 4), as shown with box 306; and a second SiGe:B layer is deposited onto the first SiGe:B layer, e.g., the second SiGe:B layer 206 (shown in FIG. 4), as shown with box 308. It is contemplated that a Si:B layer be deposited onto the second SiGe:B layer, e.g., the Si:B layer 208 (shown in FIG. 4), and that a semiconductor device, e.g., the semiconductor device 200 (shown in FIG. 1) be formed from a semiconductor conductor structure including the SiGe layer, the first SiGe:B layer, the second SiGe:B layer, and the Si:B layer, as shown with box 310 and box 312. The semiconductor device formed using the semiconductor structure may be a finFET semiconductor device, a GAA semiconductor device, and/or a 3D DRAM semiconductor device be formed from the semiconductor device, as shown with boxes 314-318. In certain examples, a SiGe intermediate layer, e.g., the SiGe intermediate layer 240 (shown in FIG. 4), may be deposited onto the second SiGe:B layer and the Si:B layer deposited onto the SiGe intermediate layer, as shown with box 390 and as further shown with box 310.

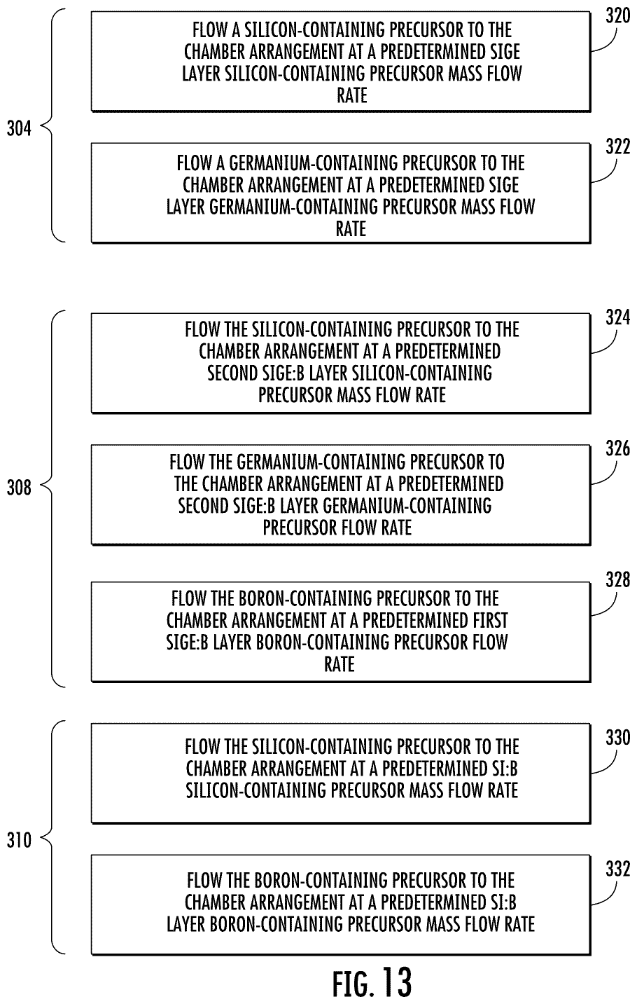

As shown in FIG. 13, depositing 304 the SiGe layer may include flowing a silicon-containing precursor at a SiGe layer silicon-containing precursor mass flow rate and a germanium-containing precursor at a SiGe layer germanium-containing precursor mass flow rate to the chamber arrangement, e.g., the silicon-containing precursor 16 (shown in FIG. 2) and the germanium-containing precursor 18 (shown in FIG. 2), as shown with box 320 and box 322. Depositing 308 the second SiGe:B layer may include flowing a silicon-containing precursor at a second SiGe:B layer silicon-containing precursor mass flow rate and flowing the germanium-containing precursor at a second SiGe:B layer germanium-containing precursor mass flow rate, as shown with box 324 and box 326. Depositing the second SiGe:B layer 308 may also include flowing a boron-containing precursor to the chamber arrangement at a second SiGe:B layer boron-containing precursor mass flow rate, e.g., the boron-containing precursor 20 (shown in FIG. 2), as shown by box 328. Depositing 310 may include flowing the silicon-containing precursor and the boron-containing precursor to the chamber arrangement at a Si:B layer silicon-containing mass flow rate and a Si:B layer boron-containing precursor mass flow rate, respectively, as shown with box 330 and box 332.

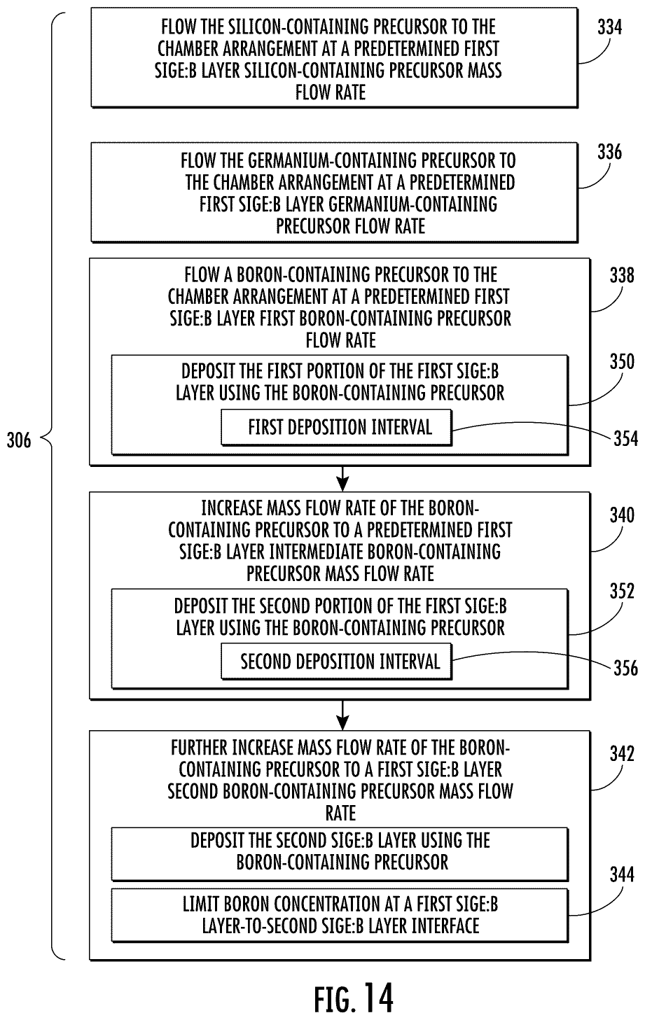

As shown in FIG. 14, depositing 306 the first SiGe:B layer may include flowing the silicon-containing precursor to the chamber arrangement at a predetermined first SiGe:B layer silicon-containing precursor mass flow rate, as shown with box 334. Depositing 306 the first SiGe:B layer may include flowing the germanium-containing precursor to the chamber arrangement at a first SiGe:B layer first germanium-containing mass flow rate, as shown with box 336. It is contemplated that the depositing 306 the first SiGe:B layer include flowing the boron-containing precursor to the chamber arrangement. In this respect it is contemplated that the boron-containing precursor initially be flowed to the chamber arrangement at a predetermined first SiGe:B layer first boron-containing precursor mass flow rate, as shown with box 338. It is further contemplated that mass flow rate of the boron-containing precursor thereafter be increased to a first SiGe:B layer intermediate boron-containing precursor mass flow rate, as shown in box 340, and that mass flow rate of the boron-containing precursor be increased from the first SiGe:B layer intermediate boron-containing precursor mass flow rate to a first SiGe:B layer second boron-containing precursor at completion of deposition of the first SiGe:B layer, as shown with box 342. Advantageously, graduated (e.g., progressive) increase in mass flow rate of the boron-containing precursor from the first SiGe:B layer first boron-containing precursor mass flow rate to the first SiGe:B layer intermediate boron-containing precursor mass flow rate—and there increasing mass flow rate of the boron-containing precursor to the first SiGe:B layer second boron-containing precursor mass flow rate may limit boron concentration at an interface of the first SiGe:B layer and the second SiGe:B layer, e.g., at the first SiGe:B layer-to second SiGe:B layer interface 234 (shown in FIG. 4), as shown with box 344. In certain examples of the present disclosure boron concentration at the interface may be less that boron concentration within the second SiGe:B layer, for example during operations where the second SiGe:B layer is deposited immediately and without interruption following deposition of the first SiGe:B layer, limiting time required to form the semiconductor structure.

With continuing reference to FIG. 12, it is contemplated that deposition of the first SiGe:B layer be accomplished by depositing a first portion of the first SiGe layer on the SiGe layer, e.g., the first portion 236 (shown in FIG. 4), and thereafter depositing a second portion of the first SiGe:B layer onto the first portion of the first SiGe:B layer, e.g., the second portion 238 (shown in FIG. 4), as shown with box 346 and box 348. Referring once again to FIG. 13, the first portion of the first SiGe:B layer may be deposited using the boron-containing precursor flowed to the chamber arrangement at the first SiGe:B layer first boron-containing precursor mass flow rate, as shown with box 350; and the second portion of the first SiGe:B layer be deposited using the boron containing precursor flowed to the chamber arrangement while increasing mass flow rate of the boron-containing precursor from the first SiGe:B layer first boron-containing precursor mass flow rate to the first SiGe:B layer intermediate boron-containing precursor mass flow rate, as shown with box 352. It is contemplated that the first portion of first SiGe:B layer be deposited during a first portion deposition interval and that the second portion of the first SiGe:B layer be deposited during a second portion deposition interval, as shown with box 354 and box 356. In certain examples, the second portion deposition interval may be shorter than the first portion deposition interval. For example, the second portion deposition interval may be between about 10% and about 40% of the first portion deposition interval, as also shown with box 354 and box 356. In accordance with certain examples, the second portion deposition interval may be longer than the first portion deposition interval. It is also contemplated that the second portion deposition interval may be substantially equivalent to the first portion deposition interval in duration and remain within the scope of the present disclosure.

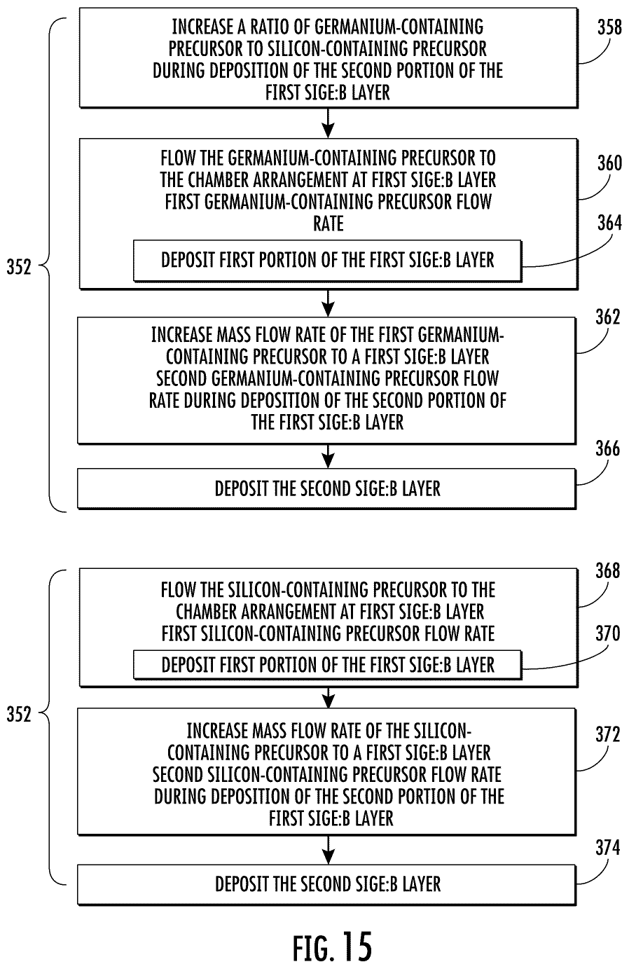

As shown in FIG. 15, depositing 352 the second portion of the first SiGe:B layer may include increasing a ratio of germanium-containing precursor mass flow rate to silicon-containing precursor mass flow rate, as shown with box 358. In certain examples of the present disclosure the ratio increase may be effected by flowing the germanium-containing precursor to the chamber arrangement a first SiGe:B layer first germanium-containing precursor mass flow rate during deposition of the first portion of the first SiGe:B layer, as shown with box 360, and thereafter increasing mass flow rate of the germanium-containing precursor to a first SiGe:B layer second germanium-containing precursor mass flow rate at the beginning of (or progressively during) deposition of the second portion of the first SiGe:B layer, as shown with box 362. It is contemplated that the first portion of the first SiGe:B layer deposited using the germanium-containing precursor flowed to the chamber arrangement at the first SiGe:B layer first germanium-containing precursor mass flow rate, as shown with box 364. It is also contemplated that the second portion of the first SiGe:B layer be deposited using the germanium-containing precursor flowed to the chamber arrangement at the first SiGe:B layer second germanium-containing precursor mass flow rate (or during a progressive increase thereto), as shown with box 366. In certain examples of the present disclosure the second germanium-containing precursor mass flow rate may be between about 150% and about 400% of the first germanium-containing precursor mass flow rate, which can limit (or prevent entirely) boron concentration change within the second portion of the first SiGe:B layer otherwise attendant with increase in mass flow rate of the boron-containing precursor from the first SiGe:B layer first boron-containing precursor mass flow rate to the first SiGe:B layer intermediate boron-containing precursor mass flow rate.

In accordance with certain examples of the present disclosure, increasing 358 of the germanium-containing precursor to the silicon-containing precursor during deposition of the second portion of the SiGe:B layer may be accompanied with increase of mass flow rate of silicon-containing precursor to the chamber arrangement. In this respect deposition of the first portion of the first SiGe:B may be accomplished while flowing the silicon-containing precursor at a first silicon-containing precursor mass flow rate, as shown with box 368 and box 370, mass flow rate of the silicon-containing precursor may thereafter be increased (e.g., according to a step function) to a first SiGe:B layer second silicon-containing precursor mass flow rate, and the second portion of the first SiGe:B layer deposited using the silicon-containing precursor flowed to the chamber arrangement at the first SiGe:B layer second silicon-containing precursor mass flow rate, as shown with box 372 and box 374. Advantageously, increasing mass flow rate of either (or both) the germanium-containing precursor and the silicon-containing precursor at the start of deposition of the second portion of the first SiGe:B layer can charge the upper chamber 170 (shown in FIG. 3) with a reservoir of available silicon and germanium atoms for incorporation into the second portion of the SiGe:B layer, offsetting the tendency that ramped increase of available boron atoms (and their associated greater affinity for incorporation) during increase from the first SiGe:B layer first boron-containing precursor to the second SiGe:B layer intermediate boron-containing precursor could otherwise have on composition of the second portion of the first SiGe:B layer.

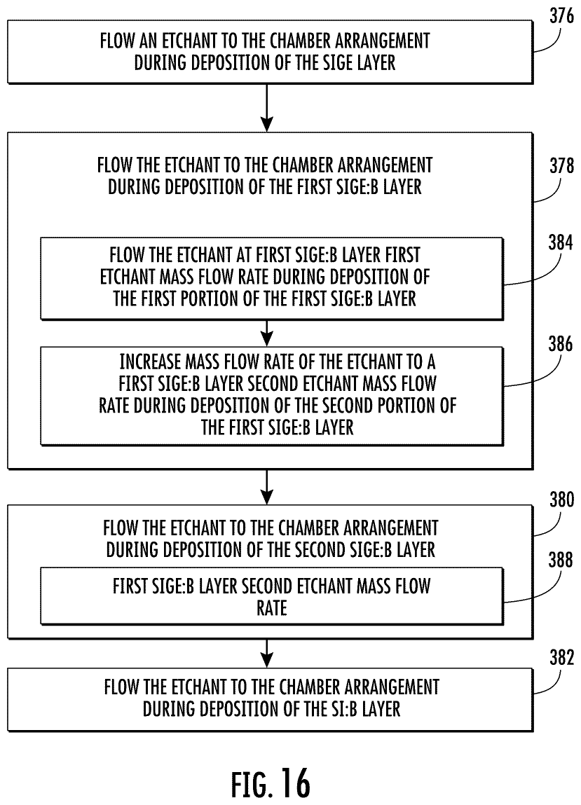

As shown in FIG. 16, it is contemplated that the method 300 include co-flowing an etchant, e.g., the etchant 24 (shown in FIG. 2), to the chamber arrangement during the forming of the semiconductor structure. In this respect the etchant may be flowed to the chamber arrangement during deposition of the SiGe layer, for example by co-flowing the etchant with either (or both) the silicon-containing precursor and the germanium-containing precursor, as shown with box 376. The etchant may also be flowed to the chamber arrangement during deposition of the first SiGe:B layer, for example by continuing co-flow of the etchant with either (or both) the silicon-containing precursor and the germanium-containing precursor and/or with the boron-containing precursor, as shown with box 378. The etchant may further be flowed to the chamber arrangement during deposition of the second SiGe:B layer, also by continuing co-flow of the etchant with either (or both) the silicon-containing precursor and the germanium-containing precursor and/or with the boron-containing precursor, as shown with box 380. It is contemplated that the etchant may additionally be flowed to the chamber arrangement during deposition of the Si:B layer, for example by co-flowing the etchant with either (or both) the silicon-containing precursor and/or the boron-containing precursor, as shown with box 382. As will be appreciated by those of skill in the art in view of the present disclosure, flowing the etchant to the chamber arrangement during forming of the semiconductor structure can make the deposition of the aforementioned layers selective, e.g., by removing amorphous material deposited onto dielectric surface portions of the substrate such as the channel 210 (shown in FIG. 4) and the gate 212 (shown in FIG. 4), while allowing the aforementioned layers to deposit onto the substrate.

In certain examples of the present disclosure mass flow rate of the etchant provided to the chamber arrangement may change during forming of the semiconductor structure. For example, the etchant may be flowed to the chamber arrangement at first SiGe:B layer first etchant mass flow rate during deposition of the first portion of the first SiGe:B layer, as shown with box 384, and mass flow rate of the etchant increased to a first SiGe:B layer second etchant mass flow rate during deposition of the second portion of the second SiGe:B layer, as shown with box 386. Mass flow rate of the etchant to the chamber arrangement may remain unchanged during deposition the second SiGe:B layer, e.g., mass flow rate remaining at the first SiGe:B layer second etchant mass flow rate during deposition of the second SiGe:B layer, as shown with box 388. For example, the flow of the etchant may be increased from the first SiGe:B layer first etchant mass flow rate to a first SiGe:B layer second etchant mass flow rate that is between about 150% and about 600% of the first SiGe:B layer first etchant mass flow rate. Advantageously, increasing mass flow rate of the etchant within these ranges can compensate for change in composition of amorphous material attendant with the above-described changes in mass flow rate of the one or more of the silicon-containing precursor, the germanium-containing precursor, and the boron-containing precursor, enable the deposition on substrates having both exposed silicon surfaces and dielectric surfaces (e.g., on patterned substrates) to remain selective notwithstanding adjustments to mass flow rates to limit boron concentration increase at the first SiGe:B layer-to second SiGe:B layer interface as described above.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A method of making a semiconductor structure, comprising:
seating a substrate on a substrate support arranged within a chamber arrangement of a semiconductor processing system;
flowing a boron-containing precursor to the chamber arrangement at a first boron-containing precursor mass flow rate;
depositing a first portion of a first SiGe:B layer using the boron-containing precursor;
increasing mass flow rate of the boron-containing precursor to an intermediate boron-containing precursor flow rate;
depositing a second portion of the first SiGe:B layer using the boron-containing precursor;
further increasing mass flow rate of the boron-containing precursor to the chamber arrangement to a second boron-containing precursor mass flow rate; and
depositing a second SiGe:B layer onto the first SiGe:B layer using the boron-containing precursor;
whereby the increase in the mass flow rate of the boron-containing precursor to the intermediate boron-containing precursor mass flow rate limits boron concentration at a first SiGe:B layer-to-second SiGe:B layer interface defined between the first SiGe:B layer and the second SiGe:B layer to less than a boron concentration within the second SiGe:B layer.

2. The method of claim 1, wherein the first portion of the first SiGe:B layer is formed during a first portion deposition interval, wherein the second portion of the first SiGe:B layer is formed during a second portion deposition interval, and wherein the second portion deposition interval is shorter than the first portion deposition interval.

3. The method of claim 2, wherein the second portion deposition interval is between about 10% and about 40% of the first portion deposition interval.

4. The method of claim 2, wherein mass flow rate of the boron-containing precursor is substantially constant during the first portion deposition interval.

5. The method of claim 2, wherein mass flow rate of the boron-containing precursor is progressively increased during the second portion deposition interval.

6. The method of claim 1, further comprising:
flowing a silicon-containing precursor to the chamber arrangement during deposition of the first portion of the first SiGe:B layer;
flowing a germanium-containing precursor to the chamber arrangement during deposition of the first portion of the first SiGe:B layer; and
increasing a ratio of germanium-containing precursor mass flow rate to silicon-containing precursor mass flow rate during deposition of the second portion of the first SiGe:B layer.

7. The method of claim 6, wherein increasing the ratio of the germanium-containing precursor to the silicon-containing precursor flowed to the chamber arrangement during deposition of the second portion of the SiGe:B layer comprises:
flowing the germanium-containing precursor to the chamber arrangement at a first germanium-containing precursor mass flow rate during deposition of the first portion of the first SiGe:B layer;
increasing the first germanium-containing precursor mass flow rate to a second germanium-containing precursor mass flow rate during deposition of the second portion of the first SiGe:B layer; and
flowing the germanium-containing precursor to the chamber arrangement at the second germanium-containing precursor mass flow rate during deposition of the second SiGe:B layer.

8. The method of claim 7, wherein the second germanium-containing precursor mass flow rate is between 150% and 400% of the first germanium-containing precursor mass flow rate.

9. The method of claim 7, wherein the second germanium-containing precursor mass flow rate remains substantially constant during deposition of the second SiGe:B layer.

10. The method of claim 7, wherein mass flow rate of the germanium-containing precursor remains constant during definition of the first SiGe:B layer-to-second SiGe:B layer interface.

11. The method of claim 6, wherein increasing the ratio of the germanium-containing precursor to the silicon-containing precursor flowed to the chamber arrangement during deposition of the second portion of the SiGe:B layer comprises:
flowing the silicon-containing precursor to the chamber arrangement at a first silicon-containing precursor mass flow rate during deposition of the first portion of the first SiGe:B layer;
increasing the first silicon-containing precursor mass flow rate to a second silicon-containing precursor mass flow rate during deposition of the second portion of the first SiGe:B layer; and
flowing the silicon-containing precursor to the chamber arrangement at the second silicon-containing precursor mass flow rate during deposition of the second SiGe:B layer.

12. The method of claim 11, wherein the second silicon-containing precursor mass flow rate is between about 105% and about 125% of the first silicon-containing precursor mass flow rate.

13. The method of claim 11, wherein the first silicon-containing precursor mass flow rate flowed to the chamber arrangement remains constant during definition of a first SiGe:B layer-to-second SiGe:B layer interface between the first SiGe:B layer and the second SiGe:B layer.

14. The method of claim 1, further comprising:
flowing at etchant to the chamber arrangement at a first etchant mass flow rate during deposition of the first portion of the first SiGe:B layer;
increasing flow rate of the etchant to a second etchant mass flow rate during deposition of the second portion of the first SiGe:B layer; and
flowing the etchant to the chamber arrangement at the second etchant mass flow rate during deposition of the second SiGe:B layer.

15. The method of claim 14, wherein the second etchant mass flow rate is between about 150% and about 600% of the first etchant mass flow rate.

16. The method of claim 1, wherein the first SiGe:B layer and the second SiGe:B layer are deposited continuously and without interruption.

17. The method of claim 1, wherein the substrate comprises a trench defined within an upper surface of the substrate, the method further comprising depositing a silicon germanium (SiGe) layer onto a lower surface and sidewalls bounding the trench.

18. The method of claim 17, wherein the first SiGe:B layer is deposited within the trench and onto the SiGe layer, wherein the second SiGe:B layer protrudes above the upper surface of the substrate, and wherein the method further comprises depositing a boron-doped silicon layer onto the second SiGe:B layer.

19. The method of claim 1, further comprising;
depositing a SiGe intermediate layer onto the second SiGe:B layer; and
depositing a Si:B layer onto the SiGe intermediate layer.

20. A semiconductor structure formed using the method of claim 1, wherein the second SiGe:B layer has a greater thickness than the first SiGe:B layer, wherein the second SiGe:B layer has a greater germanium concentration that the first SiGe:B layer, and wherein the second SiGe:B layer has a greater boron concentration than the first SiGe:B layer.

21. The semiconductor structure of claim 19, further comprising:
a SiGe intermediate layer deposited onto the second SiGe:B layer; and
a Si:B layer deposited onto the SiGe intermediate layer.

22. A computer program product comprising a non-transitory machine-readable medium having instructions that, when read by a processor, cause the processor to:
seat a substrate on a substrate support arranged within a chamber arrangement of a semiconductor processing system;
flow a boron-containing precursor to the chamber arrangement at a first boron-containing precursor mass flow rate;
deposit a first portion of a first SiGe:B layer using the boron-containing precursor;
increase mass flow rate of the boron-containing precursor to an intermediate boron-containing precursor flow rate;
deposit a second portion of the first SiGe:B layer using the boron-containing precursor;
further increase mass flow rate of the boron-containing precursor to the chamber arrangement to a second boron-containing precursor mass flow rate; and
deposit a second SiGe:B layer onto the first SiGe:B layer using the boron-containing precursor, whereby the increase in the mass flow rate of the boron-containing precursor to the intermediate boron-containing precursor flow limits boron concentration at a first SiGe:B layer-to-second SiGe:B layer interface defined between the first SiGe:B layer and the second SiGe:B layer to less than a boron concentration within the second SiGe:B layer.
